(19) United States
(12) Patent Application Publication
(10) Pub. No.: US 2004/0214454 A1
(43) Pub. Date: Oct. 28, 2004

(54) Method and apparatus for manufacturing woven connectors

(75) Inventors: Matthew Sweetland, Bedford, MA (US); James Morgan, Somerville, MA (US); Andrew Wallace, Allston, MA (US)

Correspondence Address: Neil P. Ferraro, Wolf, Greenfield & Sacks, P.C., 600 Atlantic Avenue, Boston, MA, 02210, US

(73) Assignee: Tribotek, Inc., Burlington, MA

(21) Appl. No.: 10/850,316

(22) Filed: May 20, 2004

Related U.S. Application Data
(63) Continuation-in-part of application No. 10/603,047, filed on Jun. 24, 2003.
Application No. 10/603,047 is a continuation-in-part of application No. 10/375,481, filed on Feb. 27, 2003.
Application No. 10/375,481 is a continuation-in-part of application No. 10/273,241, filed on Oct. 17, 2002.
(60) Provisional application No. 60/348,588, filed on Jan. 15, 2002.

(51) Int. Cl. H05K 1/00

(52) U.S. Cl. 439/67; 29/884; 29/857

(57) ABSTRACT

The present disclosure is directed to an apparatus and methods of manufacturing woven, electrical connectors that have a first and second set of strands defining their weave, thereby forming a locally compliant connector capable of accommodating asperities. Strands of the first set, that provide the electrical contact points of the connector, are deformed to define passageways there through. Loading strands of the second set are then extended from a driving mechanism and through the passageways to form the weave of the connector. The strands of the first set are connected to a termination of the connector and the strands of the second set are loaded by being connected to an elastic element, thereby providing compliance to the weave.

### RELATED APPLICATIONS

This patent application is a continuation-in-part of U.S. patent application Ser. No. 10/603,047, filed Jun. 24, 2003, which is a continuation-in-part of U.S. patent application Ser. No. 10/375,481, filed Feb. 27, 2003, which is a continuation-in-part of U.S. patent application Ser. No. 10/273,241, filed Oct. 17, 2002, which claims priority to U.S. Provisional Patent Application Ser. No. 60/348,588 filed Jan. 15, 2002.

### BACKGROUND OF INVENTION

1. Field of Invention

The present invention is directed to electrical connectors and in particular to woven electrical connectors and methods and apparatus used to manufacture them.

2. Discussion of Related Art

Components of electrical systems sometimes need to be interconnected using electrical connectors to provide an overall, functioning system. These components may vary in size and complexity, depending on the type of system. For example, referring to FIG. 1, a system may include a backplane assembly comprising a backplane or motherboard 30 and a plurality of daughter boards 32 that may be interconnected using a connector 34, which may include an array of many individual pin connections for different traces etc., on the boards. For example, in telecommunications applications where the connector connects a daughter board to a backplane, each connector may include as many as 2000 pins or more. Alternatively, the system may include components that may be connected using a single-pin coaxial or other type of connector, and many variations in-between. Regardless of the type of electrical system, advances in technology have led electronic circuits and components to become increasingly smaller and more powerful. However, individual connectors are still, in general, relatively large compared to the sizes of circuit traces and components.

Referring to FIGS. 2a and 2b, there are illustrated perspective views of the backplane assembly of FIG. 1. FIG. 2a also illustrates an enlarged section of the male portion of connector 34, including a housing 36 and a plurality of pins 38 mounted within the housing 36. FIG. 2b illustrates an enlarged section of the female portion of connector 34 including a housing 40 that defines a plurality of openings 42 adapted to receive the pins 38 of the male portion of the connector.

A portion of the connector 34 is shown in more detail in FIG. 3a. Each contact of the female portion of the connector includes a body portion 44 mounted within one of the openings (FIG. 2b, 42). A corresponding pin 38 of the male portion of the connector is adapted to mate with the body portion 44. Each pin 38 and body portion 44 includes a termination contact 48. As shown in FIG. 3b, the body portion 44 includes two cantilevered arms 46 adapted to provide an “interference fit” for the corresponding pin 38. In order to provide an acceptable electrical connection between the pin 38 and the body portion 44, the cantilevered arms 46 are constructed to provide a relatively high clamping force. Thus, a high normal force is required to mate the male portion of the connector with the female portion of the connector. This may be undesirable in many applications, as will be discussed in more detail below.

When the male portion of the conventional connector is engaged with the female portion, the pin 38 performs a “wiping” action as it slides between the cantilevered arms 46, requiring a high normal force to overcome the clamping force of the cantilevered arms and allow the pin 38 to be inserted into the body portion 44. There are three components of friction between the two sliding surfaces (the pin and the cantilevered arms) in contact, namely asperity interactions, adhesion and surface plowing. Surfaces, such as the pin 38 and cantilevered arms 46, that appear flat and smooth to the naked eye are actually uneven and rough under magnification. Asperity interactions result from interference between surface irregularities as the surfaces slide over each other. Asperity interactions are both a source of friction and a source of particle generation. Similarly, adhesion refers to local welding of microscopic contact points on the rough surfaces that results from high stress concentrations at these points. The breaking of these welds as the surfaces slide with respect to one another is a source of friction.

In addition, particles may become trapped between the contacting surfaces of the connector. For example, referring to FIG. 4a, there is illustrated an enlarged portion of the conventional connector of FIG. 3b, showing a particle 50 trapped between the pin 38 and cantilevered arm 46 of connector 34. The clamping force 52 exerted by the cantilevered arms must be sufficient to cause the particle to become partially embedded in one or both surfaces, as shown in FIG. 4b, such that electrical contact may still be obtained between the pin 38 and the cantilevered arm 46. If the clamping force 52 is insufficient, the particle 50 may prevent an electrical connection from being formed between the pin 38 and the cantilevered arm 46, which results in failure of the connector 34. However, the higher the clamping force 52, the higher must be the normal force required to insert the pin 38 into the body portion 44 of the female portion of the connector 34. When the pin slides with respect to the arms, the particle cuts a groove in the surface(s). This phenomenon is known as “surface plowing” and is a third component of friction.

Referring to FIG. 5, there is illustrated an enlarged portion of a contact point between the pin 38 and one of the cantilevered arms 46, with a particle 50 trapped between them. When the pin slides with respect to the cantilevered arm, as indicated by arrow 54, the particle 50 plows a groove 56 into the surface 58 of the cantilevered arm and/or the surface 60 of the pin. The groove 56 causes wear of the connector, and may be particularly undesirable in gold-plated connectors where, because gold is a relatively soft metal, the particle may plow through the gold-plating, exposing the underlying substrate of the connector. This accelerates wear of the connector because the exposed connector substrate, which may be, for example, copper, can easily oxidize. Oxidation can lead to more wear of the connector due to the presence of oxidized particles, which are very abrasive. In addition, oxidation leads to degradation in the electrical contact over time, even if the connector is not removed and re-inserted.

One conventional solution to the problem of particles being trapped between surfaces is to provide one of the surface with “particle traps.” Referring to FIGS. 6a-c, a first surface 62 moves with respect to a second surface 64 in a direction shown by arrow 66. When the surface 64 is not provided with particle traps, a process called agglomeration causes small particles 68 to combine as the surfaces move and form a large agglomerated particle 70, as illustrated in the sequence of FIGS. 6a-6c. This is undesirable, as a larger particle means that the clamping force required to break through the particle, or cause the particle to become embedded in one or both of the surfaces, so that an electrical connection can be established between surface 62 and surface 64 is very high. Therefore, the surface 64 may be provided with particle traps 72, as illustrated in FIGS. 6d-6g, which are small recesses in the surface as shown. When surface 62 moves over surface 64, the particle 68 is pushed into the particle trap 72, and is thus no longer available to cause plowing or to interfere with the electrical connection between surface 62 and surface 64. However, a disadvantage of these conventional particle traps is that it is significantly more difficult to machine surface 64 with traps than without, which adds to the cost of the connector. The particle traps also produce features that are prone to increased stress and fracture, and thus the connector is more likely to suffer a catastrophic failure than if there were no particle traps present.

### SUMMARY OF INVENTION

Connectors that can accommodate asperities, such as surface irregularities, loose particles, or agglomerate particles may be formed by allowing portions of the connector to move while other portions remain in contact, thereby accommodating the asperity while maintaining electrical connectivity. Such connectors may be formed by weaving electrically conductive strands in a manner that allows at least portions of the strand to move. Methods and apparatuses for providing such a woven electrical connector are contemplated in the present application.

According to one aspect of the invention, a method of forming a woven electrical connector comprises providing a first set of strands and a second set of strands. Strands of the first set are plastically deformed to define passageways and then strands of the second set are inserted through the passageways to form the woven electrical connector.

According to another aspect of the invention, a method of forming a woven electrical connector comprises providing a first set of strands and a second strand. The method also includes plastically deforming strands of the first set to define a passageway and then inserting the second strand through the passageway to form the woven electrical connector.

According to another aspect of the invention, a method of forming a woven electrical connector comprises providing a first strand and a second set of strands. The method also comprises plastically deforming the first strand to define passageways and then inserting strands of the second set through the passageway to form the woven electrical connector.

According to another aspect of the invention, a method of forming a woven, electrical connector comprises providing a first set of strands constructed and arranged to define passageways there through, providing a second set of substantially flexible strands, and extending strands of the second set from a driving mechanism and into the passageways of the first set to form the woven, electrical connector.

According to yet another aspect of the invention, a method of forming a woven, electrical connector comprises providing at least a first and second formed strand. Each of the first and second formed strands define a plurality of passageways there through. The plurality of passageways of each of the first and second formed strands are aligned. Further, strands of a second set are inserted through the passageways of each of the first and second strands to form the woven, electrical connector.

According to yet another aspect of the invention, a method of forming a woven electrical connector comprises providing a first set of strands consisting of electrically conductive strands and providing a second set of strands consisting of substantially inelastic, non-conductive strands. The method then includes wrapping strands of the first set about a first pin of a forming fixture to define a first passageways, wrapping strands of the first set about a second pin of the forming fixture to define a second passageways and removing at least one of the first pin or the second pin from the respective first or second passageways of the first set of strands. Also, the method includes retaining at least the other of the first pin or the second pin in the respective first or second passageway of the first set of strands as a pin of a storage magazine placing the storage magazine into a fixture to hold the first set of strands for subsequent trimming of strands of the first set and trimming a first end of each strand of the first set so each of the first ends are substantially aligned with one another. Then, the method comprises placing the storage magazine into a fixture to hold the first set of strands for subsequent insertion of strands of the second set into the passageways, driving a first of the strands of the second set between a pair of opposed wheels, guiding the first of the strands of the second set into one of the passageways, and cutting the first of the strands of the second set once inserted into the one of the passageways.

According to still another aspect of the invention, an apparatus for forming a woven, electrical connector comprises a fixture adapted to retain a first set of strands that define passageways there through. Also, a driving mechanism is adapted to extend strands of a second set away from the driving mechanism and into passageways of the first set of strands.

### BRIEF DESCRIPTION OF DRAWINGS

The foregoing and other features and advantages of the present invention will be apparent from the following non-limiting discussion of various embodiments and aspects thereof with reference to the accompanying drawings, in which like reference numerals refer to like elements throughout the different figures. The drawings are provided for the purposes of illustration and explanation, and are not intended to limit the breadth of the present disclosure.

The accompanying drawings, are not intended to be drawn to scale. In the drawings, each identical or nearly identical component that is illustrated in various figures is represented by a like numeral. For purposes of clarity, not every component may be labeled in every drawing. In the drawings:

FIG. 1 is a perspective view of a conventional backplane assembly;

FIG. 2a is a perspective view of a conventional backplane assembly showing an enlarged portion of a conventional male connector element;

FIG. 2b is a perspective view of a conventional backplane assembly showing an enlarged portion of a conventional female connector element;

FIG. 3a is a cross-sectional view of a conventional connector as may be used with the backplane assemblies of FIGS. 1, 2a, and 2b;

FIG. 3b is an enlarged cross-sectional view of a single connection of the conventional connector of FIG. 3a;

FIG. 4a is an illustration of an enlarged portion of the conventional connector of FIG. 3b, showing a trapped particle;

FIG. 4b is an illustration of the enlarged connector portion of FIG. 4a, with the particle embedded into a surface of the connector;

FIG. 5 is a diagrammatic representation of an example of the plowing phenomenon;

FIGS. 6a-g are diagrammatic representations of particle agglomeration, with and without particle traps present in a connector;

FIG. 7 is a perspective view of one embodiment of a woven connector according to aspects of the present disclosure;

FIG. 8 is a perspective view of an example of an enlarged portion of the woven connector of FIG. 7;

FIGS. 9a and 9b are enlarged cross-sectional views of a portion of the connector of FIG. 8;

FIG. 10 is a schematic representation of the connector of FIG. 7 with movable, tensioning end walls;

FIG. 11 is a schematic representation of the connector of FIG. 7 including spring members attaching the non-conductive weave fibers to the end walls;

FIG. 12 is a perspective view of an example of a tensioning mount;

FIG. 13a is an enlarged cross-sectional view of the woven connector of FIGS. 7 and 8;

FIG. 13b is an enlarged cross-sectional view of the woven connector of FIGS. 7 and 8 with a particle;

FIG. 14 is plan view of an enlarged portion of the woven connector of FIG. 7;

FIGS. 15a-b show perspective views of the connector of FIG. 7, with a mating connector element;

FIG. 16a is a perspective view of another embodiment of a connector according to aspects of the present disclosure;

FIG. 16b is a perspective view of the connector of FIG. 16a with mating connector element disengaged;

FIG. 17a is a perspective view of another embodiment of a connector according to aspects of the present disclosure;

FIG. 17b is a perspective view of the connector of FIG. 17a with mating connector element disengaged;

FIG. 18 is a perspective view of another embodiment of a woven connector according to aspects of the present disclosure;

FIG. 19 is an enlarged cross-sectional view of a portion of the connector of FIG. 18;

FIG. 20a is a perspective view of an example of a mating connector element for use with the connector of FIG. 18;

FIG. 20b is a cross-sectional view of another example of the mating connector element;

FIG. 21 is a perspective view of another example of a mating connector element that may form part of the connector of FIG. 18;

FIG. 22 is a perspective view of another example of a mating connector element, including a shield, that may form part of the connector of FIG. 18;

FIG. 23 is a perspective view of an array of woven connectors according to aspects of present disclosure;

FIG. 24 is a cross-sectional view of an exemplary woven connector embodiment that illustrates the orientation of a conductive and a loading fiber;

FIGS. 25a-b illustrate alternative conductive woven connector embodiments;

FIGS. 26a-c illustrate woven connector embodiments having self-terminating conductors;

FIG. 27 illustrates the electrical resistance versus normal contact force relationship of several different woven connector embodiments;

FIGS. 28a and 28b are cross-sectional views of one woven connector embodiment in accordance with the teachings of the present disclosure;

FIG. 29 is an enlarged cross-sectional view of a woven connector embodiment having a convex contact mating surface;

FIG. 30 depicts an exemplary embodiment of a woven power connector in accordance with the teachings of the present disclosure;

FIG. 31 is rear view of the woven connector embodiment of FIG. 30;

FIGS. 32a-c depict several exemplary spring arm embodiments for use in the connector of FIG. 30;

FIG. 33 illustrates the engagement of the conductors and mating conductors of the woven connector embodiment of FIG. 30;

FIG. 34 depicts another exemplary embodiment of a woven power connector in accordance with the teachings of the present disclosure;

FIG. 35 depicts an end view of the connector of FIG. 34;

FIGS. 36a-c are schematic representations having spring arms that generate a load within the loading fibers of the woven connector embodiment of FIG. 34;

FIGS. 37a and 37b depict an exemplary embodiment of a woven data connector in accordance with the teachings of the present disclosure;

FIG. 38 depicts another exemplary embodiment of a woven power connector in accordance with the teachings of the present disclosure;

FIGS. 39a and 39b depict the woven connector element of FIG. 38 without and with a faceplate, respectively;

FIG. 40 depicts a mating connector element for use with the connector element of FIG. 38;

FIG. 41 depicts yet another exemplary embodiment of a woven power connector in accordance with the teachings of the present disclosure;

FIG. 42 depicts a conductive strand for use in a connector according to one aspect of the disclosure, with four passageways, each adapted to receive a loading strand;

FIG. 43 depicts a conductive strand according to another aspect of the disclosure;

FIG. 44 depicts loading strands being inserted into passageways defined by the conductive strands;

FIG. 45 depicts a completed weave including loading strands that have been inserted through passageways defined by conductive strands;

FIG. 46 depicts a forming fixture according to one aspect of the disclosure for use in forming a conductive strand;

FIG. 47 depicts the fixture of FIG. 46, with the right hand die removed for clarity, after a portion of the conductive strand has been wrapped about a first forming pin;

FIG. 48 depicts the fixture of FIG. 46, with the right hand die removed for clarity, after another portion of the conductive strand has been wrapped about a second forming pin;

FIG. 49 depicts the fixture of FIG. 46, with the right hand die removed for clarity, after a portion of the conductive strand has been wrapped about two additional forming pins;

FIG. 50 depicts the forming fixture of FIG. 46 after two of the forming pins have been retracted;

FIG. 51 depicts jaws of the right hand die separated from one another to release the two pins from the right hand die to allow the formed conductive strand to be removed from the work area;

FIG. 52 depicts a partially formed conductive strand formed by an alternative forming fixture;

FIG. 53 depicts a magazine loaded with multiple, formed conductive strands;

FIG. 54 depicts a magazine loaded with multiple formed conductive strands, placed onto a trimming fixture;

FIG. 55 depicts the conductive strands shown in FIG. 54 being trimmed by a cutter;

FIG. 56 depicts the magazine and trimmed conductive strands of FIG. 55 positioned onto an insertion fixture, with a loading strand being inserted into a passageway of the formed conductive strands;

FIG. 57 depicts the insertion fixture and formed conductive strands of FIG. 56 with the magazine removed and two loading strands, each inserted into a passageways of the formed conductive strands;

FIG. 58 depicts the fixture and formed conductive strands of FIG. 57 with a third loading strand being inserted into a third passageway;

FIG. 59 depicts a side view of the insertion fixture, with a top clamping surface in place, and a loading strand being inserted into a passageway from a driving mechanism;

FIG. 60 depicts a drive mechanism having a pair of opposed drive wheels and a guide tube for inserting loading strands into passageways formed in a first set of conductive strands; and

FIG. 61 depicts a coil spring used to hold loading conductive strands in place about loading strands during an embodiment of the manufacturing process.

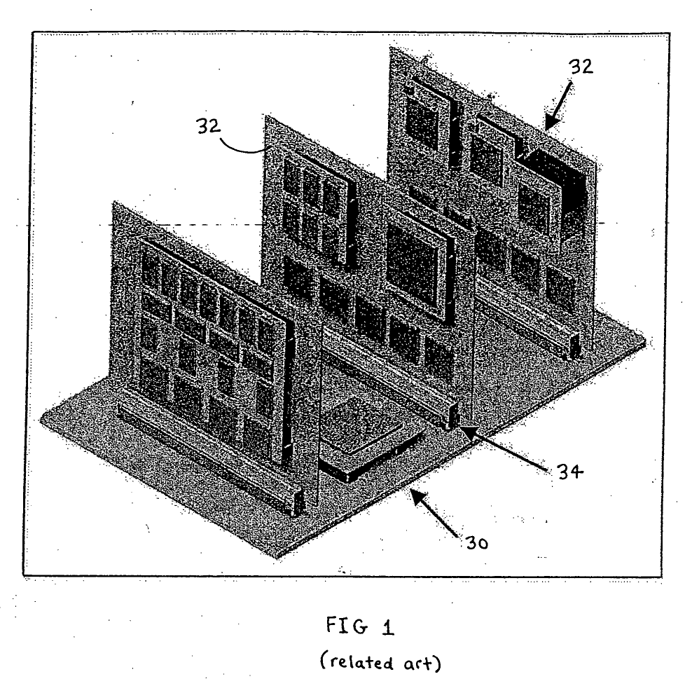

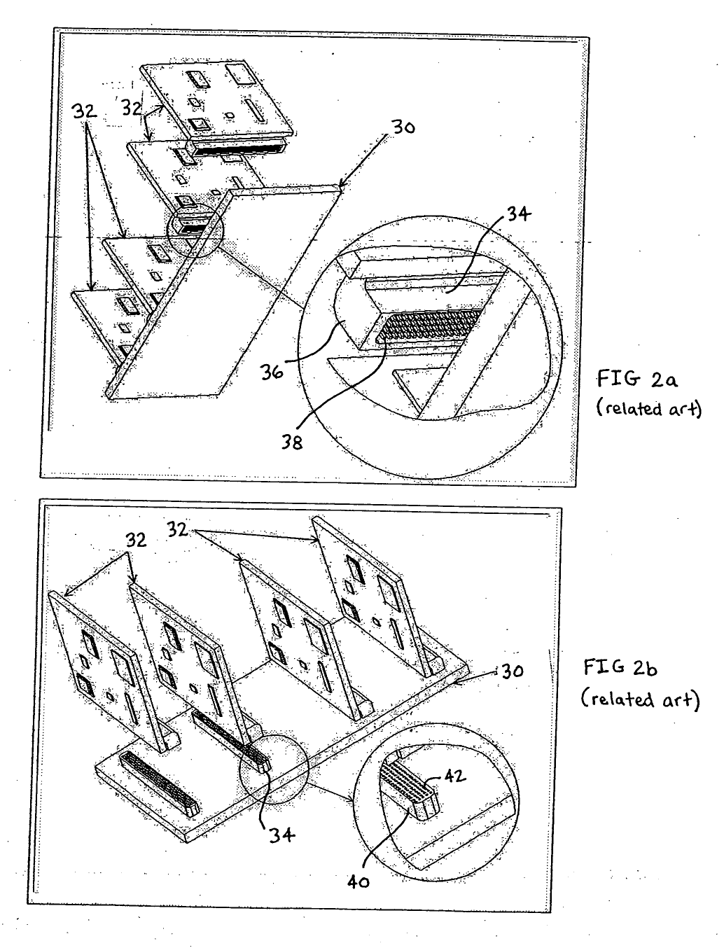

### DETAILED DESCRIPTION

The present invention provides an electrical connector that may overcome the disadvantages of prior art connectors. The present invention is also directed to methods of manufacturing connectors. The invention comprises an electrical connector capable of very high density and using only a relatively low normal force to engage a connector element with a mating connector element. It is to be understood that the invention is not limited in its application to the details of construction and the arrangement of components set forth in the following description or illustrated in the drawings. Other embodiments and manners of carrying out the invention are possible. Also, it is to be understood that the phraseology and terminology used herein is for the purpose of description and should not be regarded as limiting. The use of “including,” “comprising,” or “having” and variations thereof is meant to encompass the items listed thereafter and equivalents thereof as well as additional items. In addition, it is to be appreciated that the term “connector” as used herein refers to each of a plug and jack connector element and to a combination of a plug and jack connector element, as well as respective mating connector elements of any type of connector and the combination thereof. It is also to be appreciated that the term “conductor” refers to any electrically conducting element, such as, but not limited to, wires, conductive fibers, metal strips, metal or other conducting cores, etc.

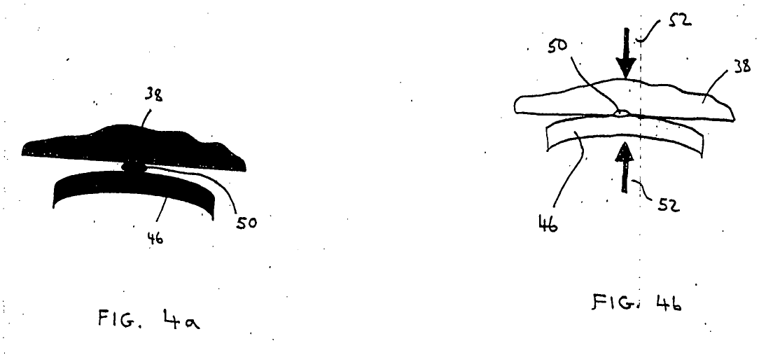

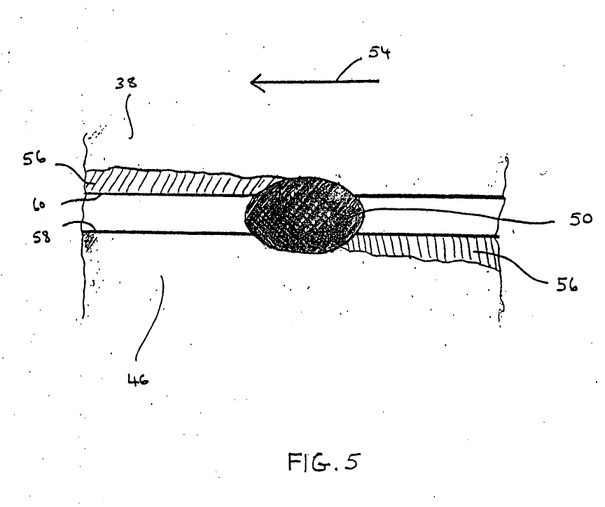

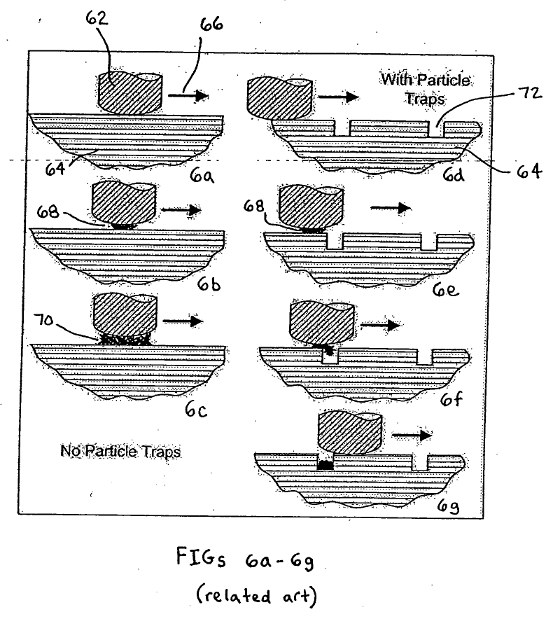

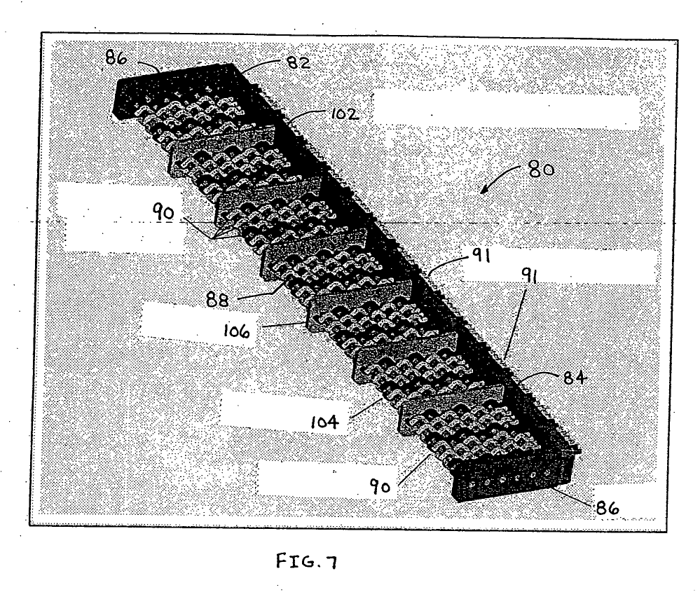

Referring to FIG. 7, there is illustrated one embodiment of a connector according to aspects of the invention. The connector 80 includes a housing 82 that may include a base member 84 and two end walls 86. A plurality of non-conductive fibers 88 may be disposed between the two end walls 86. A plurality of conductors 90 may extend from the base member 84, substantially perpendicular to the plurality of non-conductive fibers 88. The plurality of conductors 90 may be woven with the plurality of non-conductive fibers so as to form a plurality of peaks and valleys along a length of each of the plurality of conductors, thereby forming a woven connector structure. Resulting from the weave, each conductor may have a plurality of contact points positioned along the length of each of the plurality of conductors, as will be discussed in more detail below.

In one embodiment, a number of conductors 90a, for example, four conductors, may together form one electrical contact. However, it is to be appreciated that each conductor may alone form a separate electrical contact, or that any number of conductors may be combined to form a single electrical contact. The connector of FIG. 7 may be include termination contacts 91 which may be permanently or removably connected to, for example, a backplane or daughter board. In the illustrated example, the termination contacts 91 are mounted to a plate 102 that may be mounted to the base member 84 of housing 82. Alternatively, the termination may be connected directly to the base member 84 of the housing 82. The base member 84 and/or end walls 86 may also be used to secure the connector 80 to the backplane or daughter board. The connector of FIG. 7 may be adapted to engage with one or more mating connector elements, as discussed below.

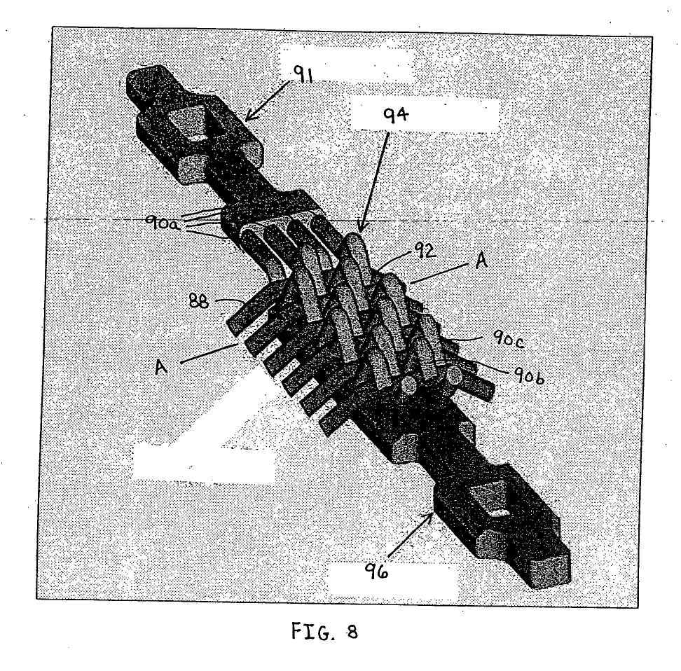

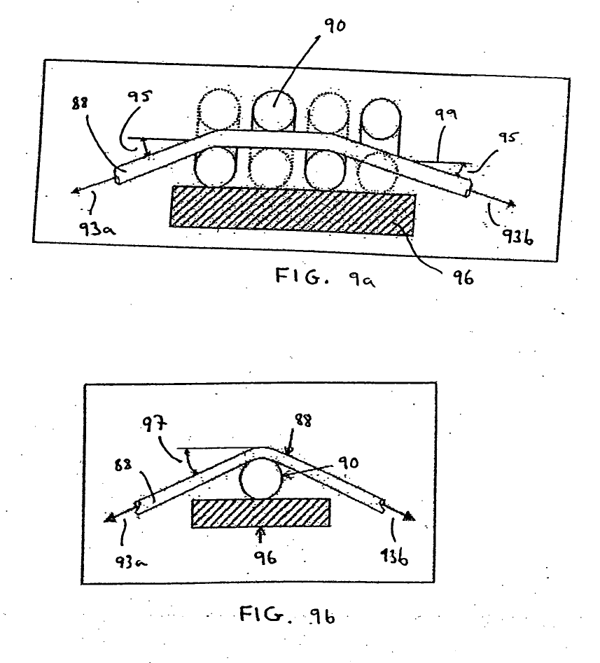

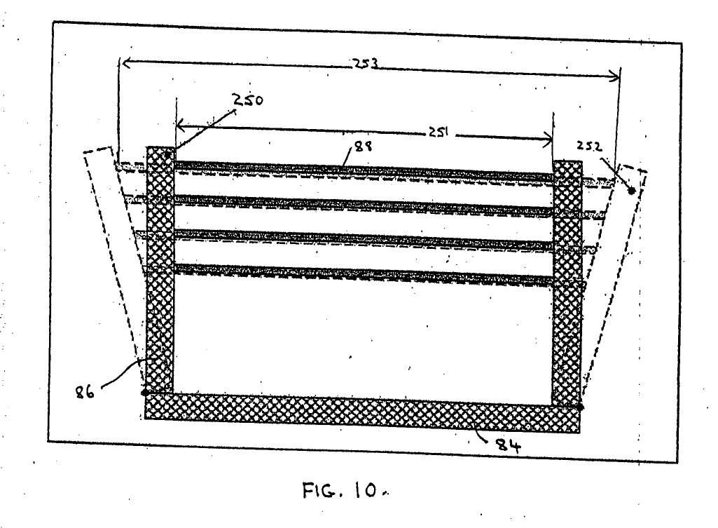

FIG. 8 illustrates an example of an enlarged portion of the connector 80, illustrating one electrical contact comprising the four conductors 90a. The four conductors 90a may be connected to a common termination contact 91. It is to be appreciated that the termination contact 91 need not have the shape illustrated, but may have any suitable configuration for termination to, for example, a semiconductor device, a circuit board, a cable, etc. According to one example, the plurality of conductors 90a may include a first conductor 90b and a second conductor 90c located adjacent the first conductor 90b. The first and second conductors may be woven with the plurality of non-conductive fibers 88 such that a first one of the non-conductive fibers 88 passes over a valley 92 of the first conductor 90b and under a peak 94 of the second conductor 90c. Thus, the plurality of contact points along the length of the conductors may be provided by either the valleys or the peaks, depending on where a contacting mating connector is located. A mating contact 96, illustrated in FIG. 8, may form part of a mating connector element 97 that may be engaged with the connector 80, as illustrated in FIG. 15b. As shown in FIG. 8, at least some of the valleys of the conductors 90a provide the plurality of contact points between the conductors 90a and the mating contact 96. It is also to be appreciated that the mating contact need not have the shape illustrated, but may have any suitable configuration for termination to, for example, a semiconductor device, a circuit board, a cable, etc.

According to one embodiment, tension in the weave of the connector 80 may provide a contact force between the conductors of the connector 80 and the mating connector 96. In one example, the plurality of non-conductive fibers 88 may comprise an elastic material. The elastic tension that may be generated in the non-conductive fibers 88 by stretching the elastic fibers, may be used to provide or impart the contact force between the connector 80 and the mating contact 96. The elastic non-conductive fibers may be prestretched to provide the elastic force, or may be mounted to tensioning mounts, as will be discussed in more detail below.

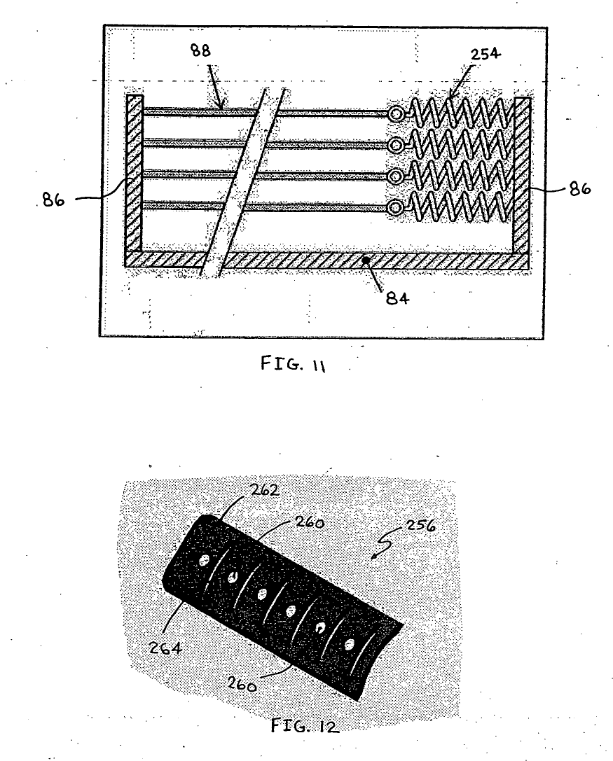

Referring to FIG. 9a, there is illustrated an enlarged cross-sectional view of the connector of FIG. 8, taken along line A-A in FIG. 8. The elastic non-conductive fiber 88 may be tensioned in the directions of arrows 93a and 93b, to provide a predetermined tension in the non-conductive fiber, which in turn may provide a predetermined contact force between the conductors 90 and the mating contact 96. In the example illustrated in FIG. 9a, the non-conductive fiber 88 may be tensioned such that the non-conductive fiber 88 makes an angle 95 with respect to a plane 99 of the mating conductor 96, so as to press the conductors 90 against the mating contact 96. In this embodiment, more than one conductor 90 may be making contact with the mating conductor 96. Alternatively, as illustrated in FIG. 9b, a single conductor 90 may be in contact with any single mating conductor 96, providing the electrical contact as discussed above. Similar to the previous example, the non-conductive fiber 86 is tensioned in the directions of the arrows 93a and 93b, and makes an angle 97 with respect to the plane of the mating contact 96, on either side of the conductor 90.

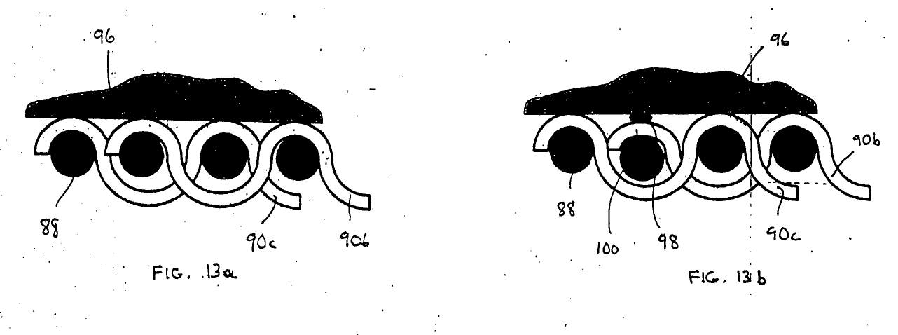

As discussed above, the elastic non-conductive fibers 88 may be attached to tensioning mounts. For example, the end walls 86 of the housing may act as tensioning mounts to provide a tension in the non-conductive fibers 88. This may be accomplished, for example, by constructing the end walls 86 to be movable between a first, or rest position 250 and a second, or tensioned, position 252, as illustrated in FIG. 10. Movement of the end walls 86 from the rest position 250 to the tensioned position 252 causes the elastic non-conductive fibers 88 to be stretched, and thus tensioned. As illustrated, the length of the non-conductive fibers 88 may be altered between a first length 251 of the fibers when the tensioning mounts are in the rest position 250, (when no mating connector is engaged with the connector 80), and a second length 253 when the tensioning mounts are in the tensioned position 252 (when a mating connector is engaged with the connector 80). This stretching and tensioning of the non-conductive fibers 88 may in turn provide contact force between the conductive weave (not illustrated in FIG. 10 for clarity), and the mating contact, when the mating connector is engaged with the connector element.

According to another example, illustrated in FIG. 11, springs 254 may be provided connected to one or both ends of the non-conductive fibers 88 and to a corresponding one or both of the end walls 86, the springs providing the elastic force. In this example, the non-conductive fibers 88 may be non-elastic, and may include an inelastic material such as, for example, a polyamid fiber, a polyaramid fiber, and the like. The tension in the non-conductive weave may be provided by the spring strength of the springs 254, the tension in turn providing contact force between the conductive weave (not illustrated for clarity) and conductors of a mating connector element. The springs 254 are illustrated as coil springs, however, any suitable spring configuration may be employed, as the present invention is not limited in this respect.

In yet another example, the non-conductive fibers 88 may be elastic or inelastic, and may be mounted to tensioning plates 256 (see FIG. 12), which may in turn be mounted to the end walls 86, or may be the end walls 86. The tensioning plates may comprise a plurality of spring members 262, each spring member defining an opening 260, and each spring member 262 being separated from adjacent spring members by a slot 264. Each non-conductive fiber may be threaded through a corresponding opening 260 in the tensioning plate 256, and may be mounted to the tensioning plate, for example, glued to the tensioning plate, or tied such that an end portion of the non-conductive fiber can not be unthreaded though the opening 260. The slots 264 may enable each spring member 262 to act independent of adjacent spring members, while allowing a plurality of spring members to be mounted on a common tensioning mount 256. Each spring member 262 may allow a small amount of motion, which may provide tension in the non-conductive weave. In one example, the tensioning mount 256 may have an arcuate structure, as illustrated in FIG. 12.

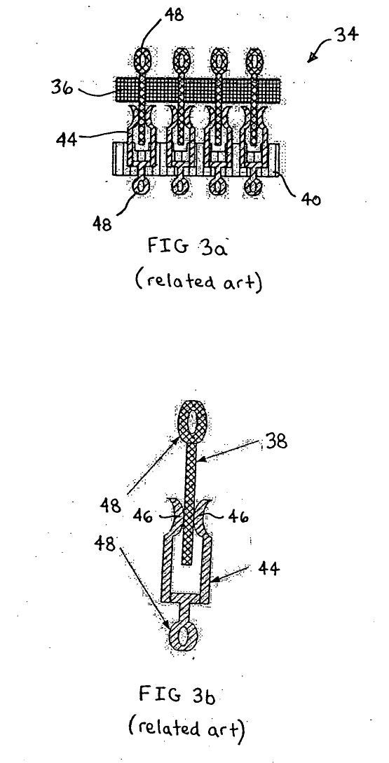

According to one aspect of the invention, providing a plurality of discrete contact points along the length of the connector and mating connector may have several advantages over the single continuous contact of conventional connectors (as illustrated in FIGS. 3a, 3b and 4). For example, when a particle becomes trapped between the surfaces of a conventional connector, as shown in FIG. 4, the particle can prevent an electrical connection from being made between the surfaces, and can cause plowing which may accelerate wear of the connector. The applicants have discovered that plowing by trapped particles is a significant source of wear of conventional connectors. The problem of plowing, and resulting lack of a good electrical connection being formed, may be overcome by the woven connectors of the present invention. The woven connectors have the feature of being “locally compliant,” which herein shall be understood to mean that the connectors have the ability to conform to a presence of small particles, without affecting the electrical connection being made between surfaces of the connector. Referring to FIGS. 13a and 13b, there are illustrated enlarged cross-sectional views of the connector of FIGS. 7 and 8, showing the plurality of conductors 90a providing a plurality of discrete contact points along the length of the mating connector element 96. When no particle is present, each peak/valley of conductors 90a may contact the mating contact 96, as shown in FIG. 13a. When a particle 98 becomes trapped between the connector surfaces, the peak/valley 100 where the particle is located, conforms to the presence of the particle, and can be deflected by the particle and not make contact with the mating contact 96, as shown in FIG. 13b. However, the other peaks/valleys of the conductors 90a remain in contact with the mating contact 96, thereby providing an electrical connection between the conductors and the mating contact 96. With this arrangement, very little force may be applied to the particle, and thus when the woven surface of the connector moves with respect to the other surface, the particle does not plow a groove in the other surface, but rather, each contact point of the woven connector may be deflected as it encounters a particle. Thus, the woven connectors may prevent plowing from occurring, thereby reducing wear of the connectors and extending the useful life of the connectors.

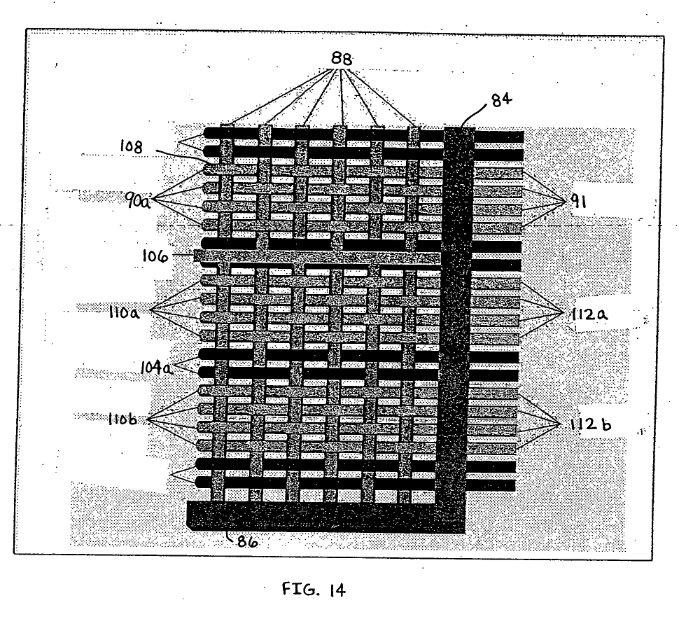

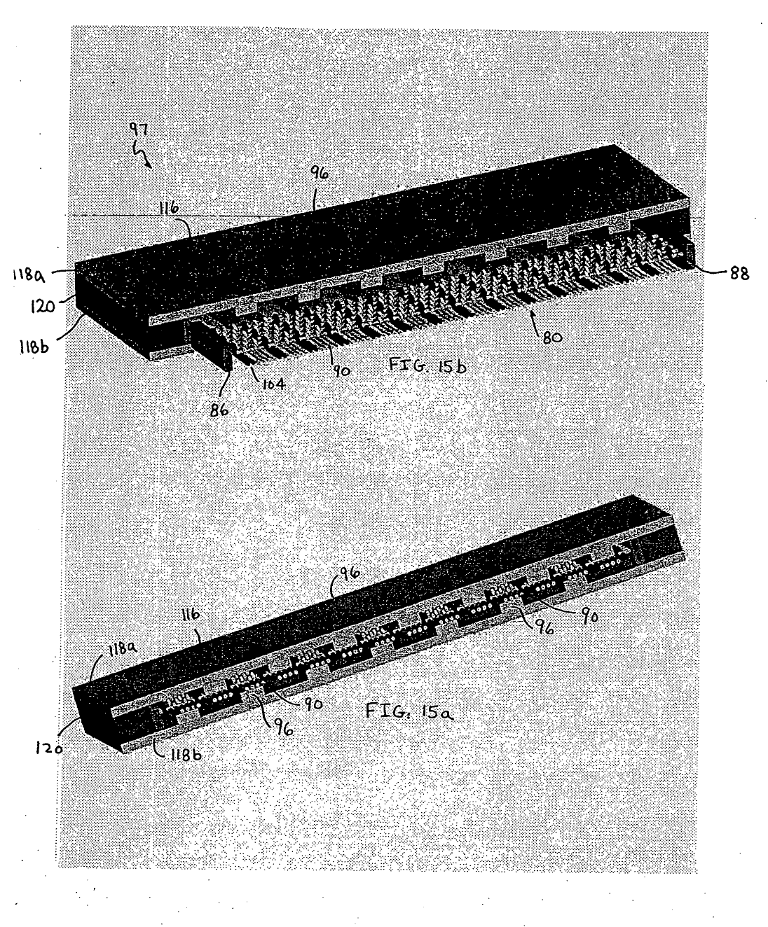

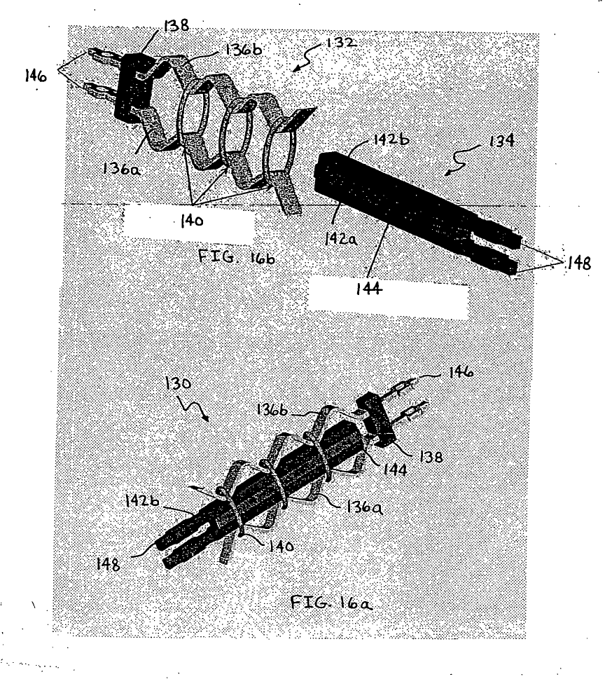

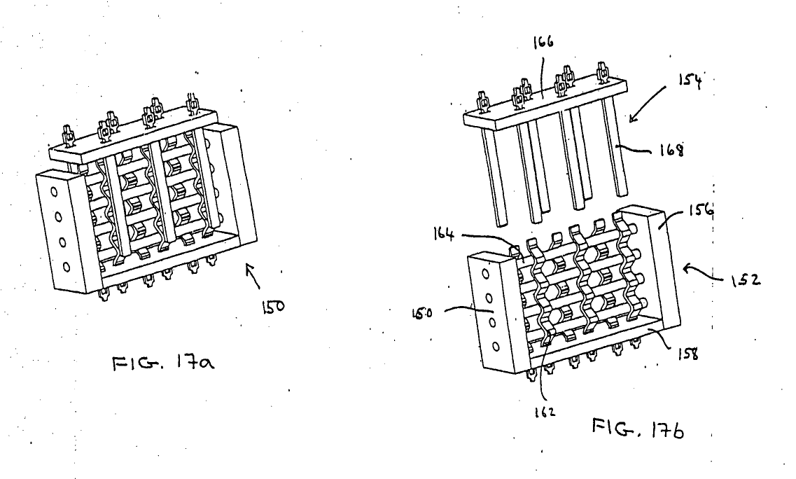

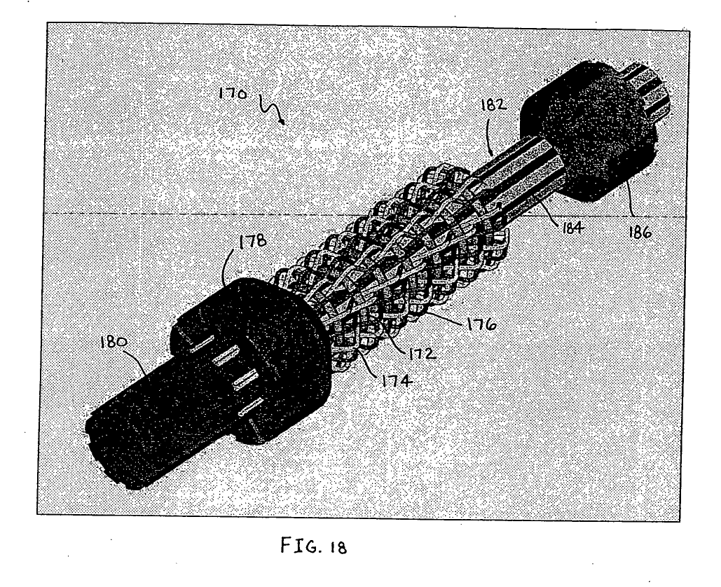

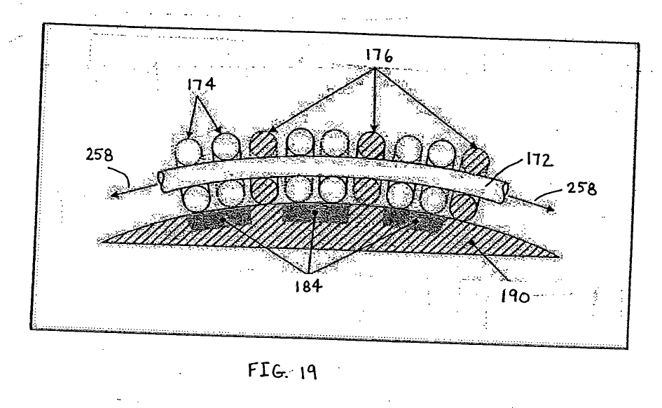

Referring again to FIG. 7, the connector 80 may further comprise one or more insulating fibers 104 that may be woven with the plurality of non-conductive fibers 88 and may be positioned between sets of conductors that together form an electrical contact. The insulating fibers 104 may serve to electrically isolate one electrical contact from another, preventing the conductors of one electrical contact from coming into contact with the conductors of the other electrical contact and causing an electrical short between the contacts. An enlarged portion of an example of connector 80 is illustrated in FIG. 14. As shown, the connector 80 may include a first plurality of conductors 110a and a second plurality of conductors 110b, separated by one or more insulating fibers 104a and woven with the plurality of non-conductive fibers 88. As discussed above, the first plurality of conductors 110a may be connected to a first termination contact 112a, forming a first electrical contact. Similarly, the second plurality of conductors 110b may be connected to a second termination contact 112b, forming a second electrical contact. In one example, the termination contacts 112a and 112b may together form a differential signal pair of contacts. Alternatively, each termination contact may form a single, separate electrical signal contact. According to another example, the connector 80 may further comprise an electrical shield member 106, that may be positioned, as shown in FIG. 7, to separate differential signal pair contacts from one another. Of course, it is to be appreciated that an electrical shield member may also be included in examples of the connector 80 that do not have differential signal pair contacts.

FIGS. 15a and 15b illustrate the connector 80 in combination with a mating connector 97. The mating connector 97 may include one or more mating contacts 96 (see FIG. 8), and may also include a mating housing 116 that may have top and bottom plate members 118a and 118b, separated by a spacer 120. The mating contacts 96 maybe mounted to the top and/or bottom plate members 118a and 118b, such that when the connector 80 is engaged with the mating connector 97, at least some of the contact points of the plurality of conductors 90 contact the mating contacts 96, providing an electrical connection between the connector 80 and mating connector 97. In one example, the mating contacts 96 may be alternately spaced along the top and bottom plate members 118a and 118b as illustrated in FIG. 15a. The spacer 120 may be constructed such that a height of the spacer 120 is substantially equal to or slightly less than a height of the end walls 86 of connector 80, so as to provide an interference fit between the connector 80 and the mating connector 97 and so as to provide contact force between the mating conductors and the contact points of the plurality of conductors 90. In one example, the spacer may be constructed to accommodate movable tensioning end walls 86 of the connector 80, as described above.

It is to be appreciated that the conductors and non-conductive and insulating fibers making up the weave may be extremely thin, for example having diameters in a range of approximately 0.0001 inches to approximately 0.020 inches, and thus a very high density connector may be possible using the woven structure. Because the woven conductors are locally compliant, as discussed above, little energy may be expended in overcoming friction, and thus the connector may require only a relatively low normal force to engage a connector with a mating connector element. This may also increase the useful life of the connector as there is a lower possibility of breakage or bending of the conductors occurring when the connector element is engaged with the mating connector element. Pockets or spaces present in the weave as a natural consequence of weaving the conductors and insulating fibers with the non-conductive fibers may also act as particle traps. Unlike conventional particle traps, these particle traps may be present in the weave without any special manufacturing considerations, and do not provide stress features, as do conventional particle traps.

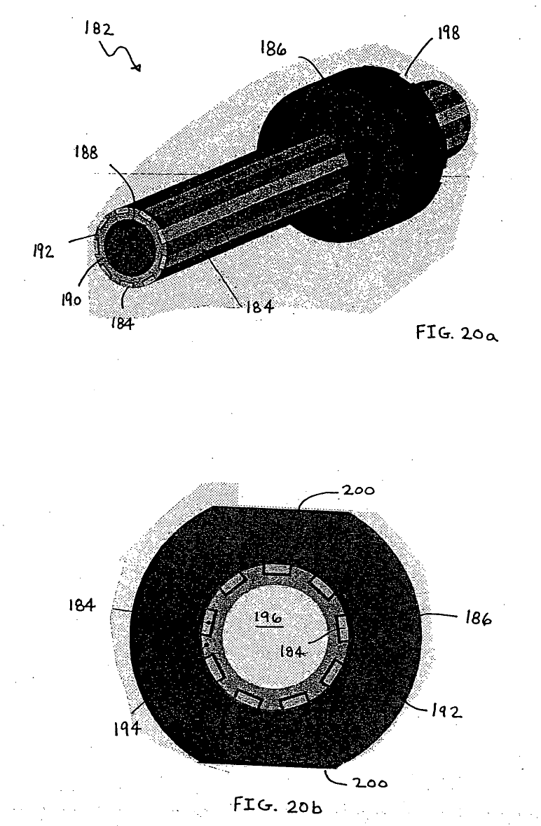

Referring to FIGS. 16a and 16b, there is illustrated another embodiment of a woven connector according to aspects of the invention. In this embodiment, a connector 130 may include a first connector element 132 and a mating connector element 134. The first connector element may comprise first and second conductors 136a and 136b that may be mounted to an insulating housing block 138. It is to be appreciated that although in the illustrated example the first connector element includes two conductors, the invention is not so limited and the first connector element may include more than two conductors. The first and second conductors may have an undulating form along a length of the first and second conductors, as illustrated, so as to include a plurality of contact points 139 along the length of the conductors. In one example of this embodiment, the weave is provided by a plurality of elastic bands 140 that encircle the first and second conductors 136a and 136b. According to this example, a first elastic band may pass under a first peak of the first conductor 136a and over a first valley of the second conductor 136b, so as to provide a woven structure having similar advantages and properties to that described with respect to the connector 80 (FIGS. 7-15b) above. The elastic bands 140 may include an elastomer, or may be formed of another insulating material. It is also to be appreciated that the bands 140 need not be elastic, and may include an inelastic material. The first and second conductors of the first connector element may be terminated in corresponding first and second termination contacts 146, which may be permanently or removably connected to, for example, a backplane, a circuit board, a semiconductor device, a cable, etc.

As discussed above, the connector 130 may further comprise a mating connector element (rod member) 134, which may comprise third and fourth conductors 142a, 142b separated by an insulating member 144. When the mating connector element 134 is engaged with the first connector element 132, at least some of the contact points 139 of the first and second conductors may contact the third and fourth conductors, and provide an electrical connection between the first connector element and the mating connector element. Contact force may be provided by the tension in the elastic bands 140. It is to be appreciated that the mating connector element 134 may include additional conductors adapted to contact any additional conductors of the first connector element, and is not limited to having two conductors as illustrated. The mating connector element 134 may similarly include termination contacts 148 that may be permanently or removably connected to, for example, a backplane, a circuit board, a semiconductor device, a cable, etc.

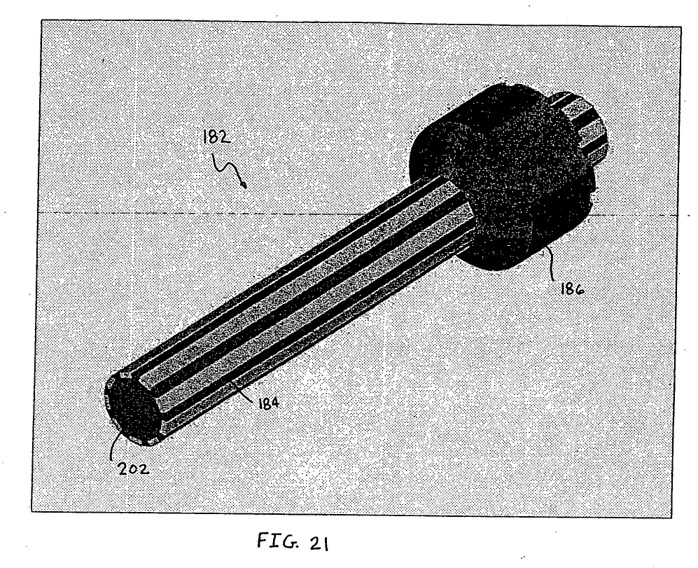

An example of another woven connector according to aspects of the invention is illustrated in FIGS. 17a and 17b. In this embodiment, a connector 150 may include a first connector element 152 and a mating connector element 154. The first connector element 152 may comprise a housing 156 that may include a base member 158 and two opposing end walls 160. The first connector element may include a plurality of conductors 162 that may be mounted to the base member and may have an undulating form along a length of the conductors, similar to the conductors 136a and 136b of connector 130 described above. The undulating form of the conductors may provide a plurality of contact points along the length of the conductors. A plurality of non-conductive fibers 164 may be disposed between the two opposing end walls 160 and woven with the plurality of conductors 162, forming a woven connector structure. The mating connector element 154 may include a plurality of conductors 168 mounted to an insulating block 166. When the mating connector element 154 is engaged with the first connector element 152, as illustrated in FIG. 17b, at least some of the plurality of contact points along the lengths of the plurality of conductors of the first connector element may contact the conductors of the mating connector element to provide an electrical connection therebetween. In one example, the plurality of non-conductive fibers 164 may be elastic and may provide a contact force between the conductors of the first connector element and the mating connector element, as described above with reference to FIGS. 9a and 9b. Furthermore, the connector 150 may include any of the other tensioning structures described above with reference to FIGS. 10a-12. This connector 150 may also have the advantages described above with respect to other embodiments of woven connectors. In particular, connector 150 may prevent trapped particles from plowing the surfaces of the conductors in the same manner described in reference to FIG. 13.

Referring to FIG. 18, there is illustrated yet another embodiment of a woven connector according to the invention. The connector 170 may include a woven structure including a plurality of non-conductive fibers (bands) 172 and at least one conductor 174 woven with the plurality of non-conductive fibers 172. In one example, the connector may include a plurality of conductors 174, some of which may be separated from one another by one or more insulating fibers 176. The one or more conductors 174 may be woven with the plurality of non-conductive fibers 172 so as to form a plurality of peaks and valleys along a length of the conductors, thereby providing a plurality of contact points along the length of the conductors. The woven structure may be in the form of a tube, as illustrated, with one end of the weave connected to a housing member 178. However, it is to be appreciated that the woven structure is not limited to tubes, and may have any shape as desired. The housing member 178 may include a termination contact 180 that may be permanently or removably connected to, for example, a circuit board, backplane, semiconductor device, cable, etc. It is to be appreciated that the termination contact 180 need not be round as illustrated, but may have any shape suitable for connection to devices in the application in which the connector is to be used.

The connector 170 may further include a mating connector element (rod member) 182 to be engaged with the woven tube. The mating connector element 182 may have a circular cross-section, as illustrated, but it is to be appreciated that the mating connector element need not be round, and may have another shape as desired. The mating connector element 182 may comprise one or more conductors 184 that may be spaced apart circumferentially along the mating connector element 182 and may extend along a length of the mating connector element 182. When the mating connector element 182 is inserted into the woven tube, the conductors 174 of the weave may come into contact with the conductors 184 of the mating connector element 182, thereby providing an electrical connection between the conductors of the weave and the mating connector element. According to one example, the mating connector element 182 and/or the woven tune may include registration features (not illustrated) so as to align the mating connector element 182 with the woven tube upon insertion.

In one example, the non-conductive fibers 172 may be elastic and may have a circumference substantially equal to or slightly smaller than a circumference of the mating connector element 182 so as to provide an interference fit between the mating connector element and the woven tube. Referring to FIG. 19, there is illustrated an enlarged cross-sectional view of a portion of the connector 170, illustrating that the non-conductive fibers 172 may be tensioned in directions of arrows 258. The tensioned non-conductive fibers 172 may provide contact force that causes at least some of the plurality of contact points along the length of the conductors 174 of the weave to contact the conductors 184 of the mating connector element. In another example, the non-conductive fibers 172 may be inelastic and may include spring members (not shown), such that the spring members allow the circumference of the tube to expand when the mating connector element 182 is inserted. The spring members may thus provide the elastic/tension force in the woven tube which in turn may provide contact force between at least some of the plurality of contact points and the conductors 184 of the mating connector element 182.

As discussed above, the weave is locally compliant, and may also include spaces or pockets between weave fibers that may act as particle traps. Furthermore, one or more conductors 174 of the weave may be grouped together (in the illustrated example of FIGS. 18 and 19, the conductors 174 are grouped in pairs) to provide a single electrical contact. Grouping the conductors may further improve the reliability of the connector by providing more contact points per electrical contact, thereby decreasing the overall contact resistance and also providing capability for complying with several particles without affecting the electrical connection.

Referring to FIGS. 20a and 20b, there are illustrated in perspective view and cross-section, respectively, two examples of a mating connector element 182 that may be used with the connector 170. According to one example, illustrated in FIG. 20a, the mating connector element 182 may include a dielectric or other non-conducting core 188 surrounded, or at least partially surrounded, by a conductive layer 190. The conductors 184 may be separated from the conductive layer 190 by insulating members 192. The insulating members may be separate from each conductor 184 as illustrated, or may comprise an insulating layer at least partially surrounding the conductive layer 190. The mating connector element may further include an insulating housing block 186.

According to another example, illustrated in FIG. 20b, a mating connector element 182 may comprise a conductive core 194 that may define a cavity 196 therein. Any one or more of an optical fiber, a strength member to increase the overall strength and durability of the rod member, and a heat transfer member that may serve to dissipate heat built up in the connector from the electrical signals propagating in the conductors, may be located within the cavity 196. In one example, a drain wire may be located within the cavity and may be connected to the conductive core to serve as a grounding wire for the connector. As illustrated in FIG. 20a, the housing block 186 may be round, increasing the circumference of the mating connector element, and may include one or more notches 198 that may serve as registration points for the connector to assist in aligning the mating connector element with the conductors of the woven tube. Alternatively, the housing block may include flattened portions 200, as illustrated in FIG. 20b, that may serve as registration guides. It is further to be appreciated that the housing block may have another shape, as desired and may include any form of registration known to, or developed by, one of skill in the art.

FIG. 21 illustrates yet another example of a mating connector element 182 that may be used with the connector 170. In this example, the mating connector element may include a dielectric or other non-conducting core 202 that may be formed with one or more grooves, to allow the conductors 184 to be formed therein, such that a top surface of the conductors 184 is substantially flush with an outer surface of the mating connector element.

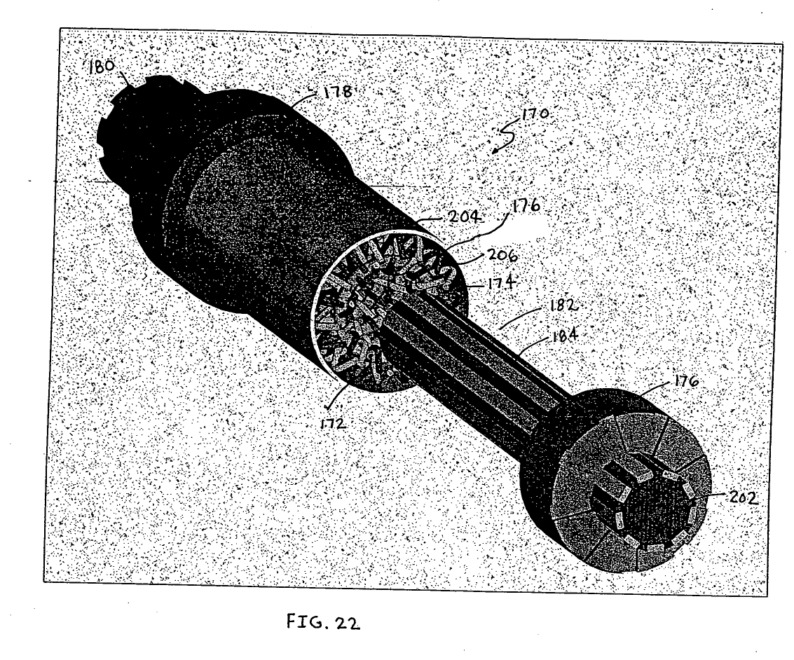

According to another example, illustrated in FIG. 22, the connector 170 may further comprise an electrical shield 204 that may be placed substantially surrounding the woven tube. The shield may comprise an non-conducting inner layer 206 that may prevent the conductors 174 from contacting the shield and thus being shorted together. In one example, the rod member may comprise a drain wire located within a cavity of the mating connector element, as discussed above, and the drain wire may be electrically connected to the electrical shield 204. The shield 204 may comprise, for example, a foil, a metallic braid, or another type of shield construction known to those of skill in the art.

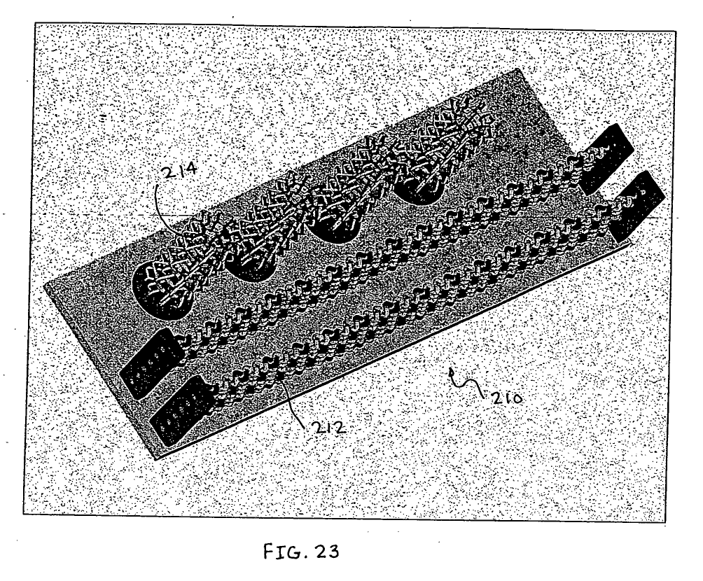

Referring to FIG. 23, there is illustrated an example of an array of woven connectors according to aspects of the invention. According to one embodiment, the array 210 may comprise one or more woven connectors 212 of a first type, and one or more woven connectors 214 of a second type. In one example, the woven connectors 212 may be the connector 80 described above in reference to FIGS. 7-15b, and may be used to connect signal traces and or components on different circuit boards to one another. The woven connectors 214 may be the connector 170 described above in reference to FIGS. 18-22, and may be used to connector power traces or components on the different circuit boards to one another. In one example where the connector 170 may be used to provide power supply connections, the rod member 180 may be substantially completely conductive. Furthermore, in this example, there may be no need to include insulating fibers 176, and the fibers 172, previously described as being non-conductive, may in fact be conductive so as to provide a larger electrical path between the woven tube and the rod member. The connectors may be mounted to a board 216, as illustrated, which may be, for example, a backplane, a circuit board, etc., which may include electrical traces and components mounted to a reverse side, or positioned between the connectors (not shown).

As discussed herein, the utilization of conductors being woven or intertwined with loading fibers, e.g., non-conductive fibers, can provide particular advantages for electrical connector systems. Designers are constantly struggling to develop (1) smaller electrical connectors and (2) electrical connectors which have minimal electrical resistance. The woven connectors described herein can provide advantages in both of these areas. The total electrical resistance of an assembled electrical connector is generally a function of the electrical resistance properties of the male-side of the connector, the electrical resistance properties of the female-side of the connector, and the electrical resistance of the interface that lies between these two sides of the connector. The electrical resistance properties of both the male and female-sides of the electrical connector are generally dependent upon the physical geometries and material properties of their respective electrical conductors. The electrical resistance of a male-side connector, for example, is typically a function of its conductor's (or conductors') cross-sectional area, length and material properties. The physical geometries and material selections of these conductors are often dictated by the load capabilities of the electrical connector, size constraints, structural and environmental considerations, and manufacturing capabilities.

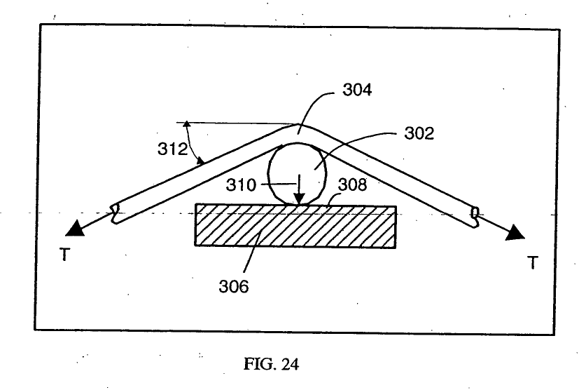

Another critical parameter of an electrical connector is to achieve a low and stable separable electrical resistance interface, i.e., electrical contact resistance. The electrical contact resistance between a conductor and a mating conductor in certain loading regions can be a function of the normal contact force that is being exerted between the two conductive surfaces. As can be seen in FIG. 24, the normal contact force 310 of a woven connector is a function of the tension T exerted by the loading fiber 304, the angle 312 that is formed between the loading fiber 304 and the contact mating surface 308 of the mating conductor 306, and the number of conductors 302 of which the tension T is acting upon. As the tension T and/or angle 312 increase, the normal contact force 310 also increases. Moreover, for a desired normal contact force 310 there may be a wide variety of tension T/angle 312 combinations that can produce the desired normal contact force 310.

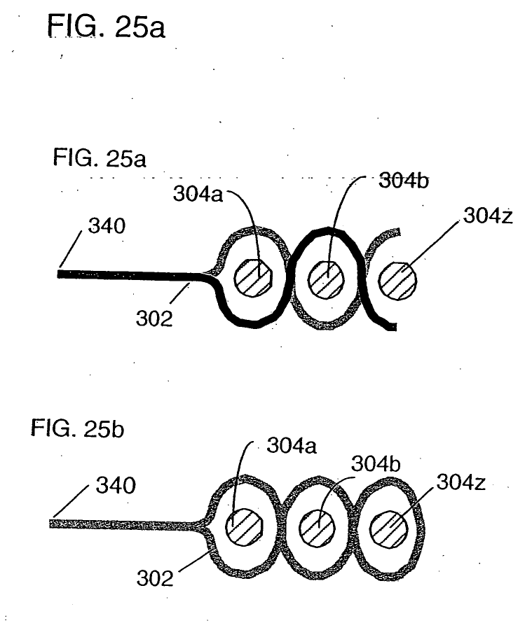

FIGS. 25a-b illustrate a method for terminating the conductors 302 that are woven onto loading fibers 304. Referring to FIG. 25a, conductor 302 winds around a first loading fiber 304a, a second loading fiber 304b and a last loading fiber 304z. The orientation and/or pattern of the conductor 302—loading fiber 304 weave can vary in other embodiments, e.g., a valley formed by a conductor 302 may encompass more than one loading fiber 304, etc. The conductors 302 on one side terminate at a termination point 340. Termination point 340 will generally comprise a termination contact, as previously discussed. In an exemplary embodiment, the conductors 302 may also terminate on the opposite side of the weave at another termination point (not shown) that, unlike termination point 340, will generally not comprise a termination contact. FIG. 25b illustrates a preferred embodiment for weaving the conductors 302 onto the loading fibers 304a-z. In FIG. 25b, the conductor 302 is woven around the first and second loading fibers 304a, 304b in the same manner as discussed above. In this preferred embodiment, however, conductor 302 then wraps around the last loading fiber 304z and is then woven around the second loading fiber 304b and then the first loading fiber 304a. Thus, the conductor 302 begins at termination point 340, is woven around the conductors 304a, 304b, wrapped around loading fiber 304z, woven (again) around loading fibers 304b, 304a, and terminates at termination point 340. Having a conductor 302 wrap around the last loading fiber 304z and becoming the next conductor (thread) in the weave eliminates the need for a second termination point. Consequently, when a conductor 302 is wrapped around the last loading fiber 304z in this manner the conductor 302 is referred to as being self-terminating.

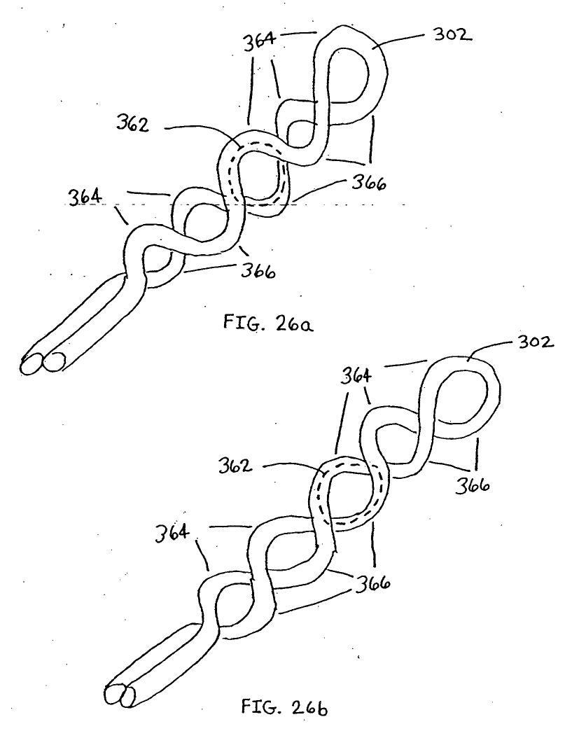

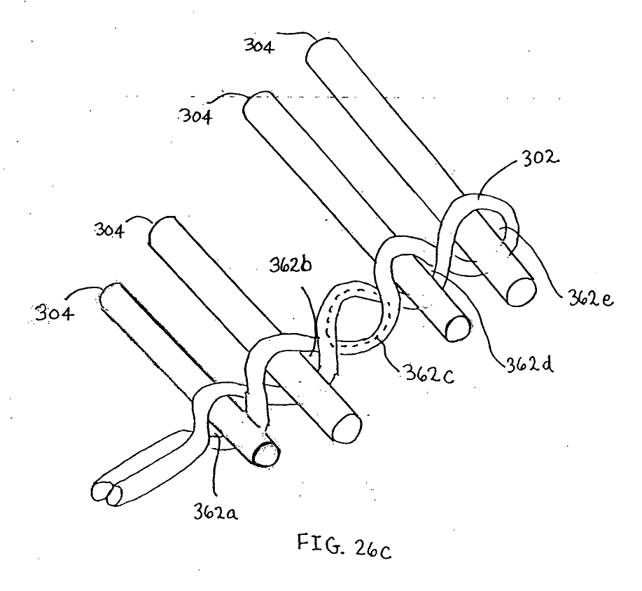

FIGS. 26a-c illustrate some exemplary embodiments of how conductor(s) 302 can be woven onto loading fibers 304. The conductor 302 of FIGS. 26a-c is self-terminating and, while only one conductor 302 is shown, persons skilled in the art will readily appreciate that additional conductors 302 will usually be present within the depicted embodiments. FIG. 26a illustrates a conductor 302 that is arranged as a straight weave. The conductor 302 forms a first set of peaks 364 and valleys 366, wraps back upon itself (i.e., is self-terminated) and then forms a second set of peaks 364 and valleys 366 that lie adjacent to and are offset from the first set of peaks 364 and valleys 366. A peak 364 from the first set and a valley 366 from the second set (or, alternatively, a valley 366 from the first set and a peak 364 from the second set) together can form a loop 362. Loading fibers 304 (not shown) can be located within (i.e., be engaged with) the loops 362. While the conductor 302 of FIGS. 26a-c is shown as being self-terminating, in other exemplary embodiments, the conductors 302 need not be self-terminating. Using non self-terminating conductors 302, to form a straight weave similar to the one disclosed in FIG. 26a, a first conductor 302 forms a first set of peaks 364 and valleys 366 while a second conductor 302 forms a second set of peaks 364 and valleys 366 which lie adjacent to and are offset from the first set. The loops 362 are similarly formed from corresponding peaks 364 and valleys 366. FIG. 26b illustrates a conductor 302 that is arranged as a crossed weave. The conductor 302 of FIG. 26b forms a first set of peaks 364 and valleys 366, wraps back upon itself and then forms a second set of peaks 364 and valleys 366 which are interwoven with, and are offset from, the first set of peaks 364 and valleys 366. Similarly, peaks 364 from the first set and valleys 366 from the second set (or, alternatively, valleys 366 from the first set and peaks 364 from the second set) together can form loops 362, which may be occupied by loading fibers 304. Non self-terminating conductors 302 may also be arranged as a crossed weave. As shown, the cross-weave alternates at every peak and valley. However, the present invention is not limited in this respect as the cross-weave may occur at every other (or some other suitable multiple) peak and valley.

FIG. 26c depicts a self-terminating conductor 302 that is cross woven onto four loading fibers 304. The conductor 302 of FIG. 26c forms five loops 362a-e. In certain exemplary embodiments, a loading fiber(s) 304 is located within each of the loops 362 that are formed by the conductors 302. However, not all loops 362 need to be occupied by a loading fiber 304. FIG. 26c, for example, illustrates an exemplary embodiment where loop 362c does not contain a loading fiber 304. It may be desirable to include unoccupied loops 362 within certain conductor 302—loading fiber 304 weave embodiments so as to achieve a desired overall weave stiffness (and flexibility). Having unoccupied loops 362 within the weave may also provide improved operations and manufacturing benefits. When the weave structure is mounted to a base, for example, there may be a slight misalignment of the weave relative to the mating conductor. This misalignment may be compensated for due to the presence of the unoccupied loop 362. Thus, by utilizing loops that are unoccupied or “unstitched”, i.e., a loading fiber 304 does not contact the loop, compliance of the weave structure to ensure better conductor/mating conductor conductivity while keeping the weave tension to a minimum may be achieved. Utilizing unoccupied loops 362 may also permit greater tolerance allowances during the assembly process. Moreover, the use of unstitched loops 362 may allow the use of common tooling for different connector embodiments (e.g., the same tooling might be used for a weave 8 having eight loops 362 with six “stitched” loading fibers 304 as for a weave having eight loops 362 with eight loading fibers 304. As an alternative to using an unstitched loop 362, a straight (unwoven) conductor 302 may be used instead.

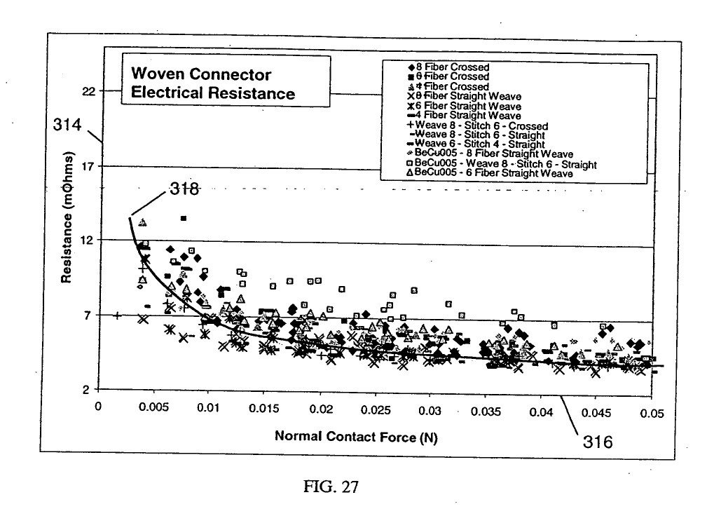

Tests of a wide variety of conductor 302—loading fiber 304 weave geometries were performed to determine the relationship between normal contact force 310 and electrical contact resistance. Referring to FIG. 27, the total electrical resistance of the tested woven connector embodiments, as represented on y-axis 314, of the different woven connector embodiments (as listed in the legend) was determined over a range of normal contact forces, as represented on x-axis 316. As represented in FIG. 27, the general trend 318 indicates that as the normal contact force (in Newtons (N)) increases, the contact resistance component of the total electrical resistance (in milli-ohms (mOhms)) generally decreases. Persons skilled in the art will readily recognize, however, that the decrease in contact resistance only extends over a certain range of normal contact forces; any further increases over a threshold normal contact force will produce no further reduction in electrical contact resistance. In other words, trend 318 tends to flatten out as one moves further and further along the x-axis 316.

From the data of FIG. 27, for example, one can then determine a normal contact force (or range thereof) that is sufficient for minimizing a woven connector's electrical contact resistance. To generate these normal contact forces, the preferred operating range of the tension T to be loaded in the loading fiber(s) 304 and the angle 312 (which is indicative of the orientation of the loading fiber(s) 304 relative to the conductor(s) 302) can then be determined for an identified woven connector embodiment. As persons skilled in the art will readily appreciate, the vast majority of the conventional electrical connectors that are available today operate with normal contact forces ranging from about 0.35 to 0.5 N or higher. As is evident by the data represented in FIG. 27, by generating multiple contact points on conductors 302 of a woven connector system, very light loading levels (i.e., normal contact forces) can be used to produce very low and repeatable electrical contact resistances. The data of FIG. 27, for example, demonstrates that for many of the woven connector embodiments tested, normal contact forces of between approximately 0.020 and 0.045 N may be sufficient for minimizing electrical contact resistance. Such normal contact forces thus represent an order of magnitude reduction in the normal contact forces of conventional electrical connectors.

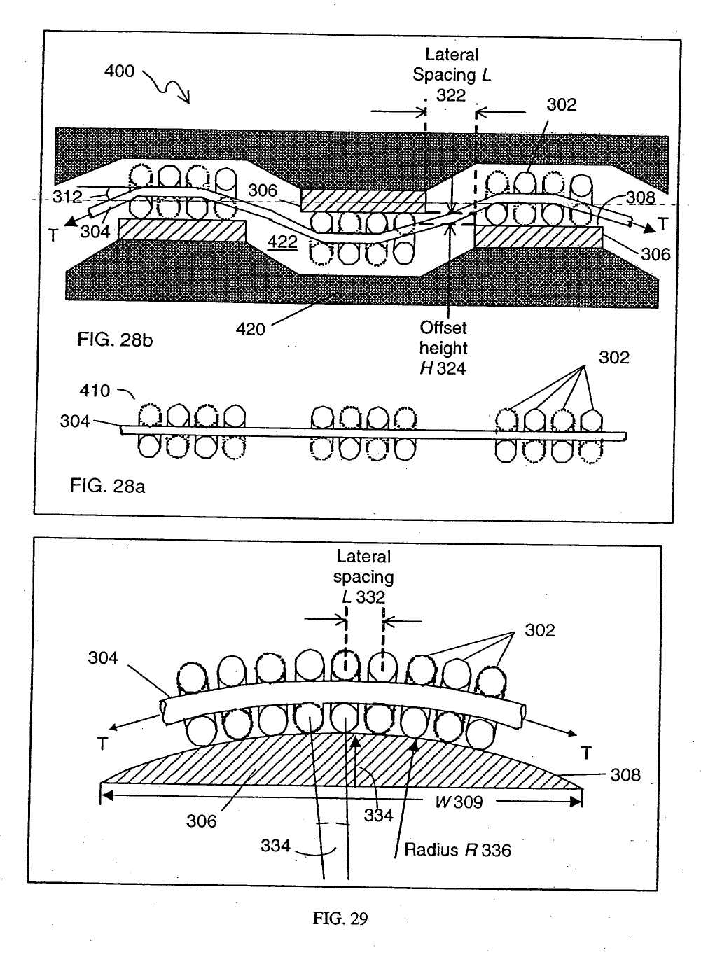

Recognizing that very low normal contact forces can be utilized in these woven multi-contact connectors, the challenge then becomes how to generate these normal contact forces reliably at each of the conductor 302's contact points. The contact points of a conductor 302 are the locations where electrical conductivity is to be established between the conductor 302 and a contact mating surface 308 of a mating conductor 306. FIGS. 28a and 28b depict an exemplary embodiment of a woven multi-contact connector 400 that is capable of generating desired normal contact forces at each of the contact points. FIGS. 28a and 28b depict cross-sectional views of a woven connector 400 having a woven connector element 410 and a mating connector element 420. The woven connector element 410 is comprises loading fiber(s) 304 and conductors 302. The ends of the loading fibers(s) 304 generally are secured to end plates (not shown) or other fixed structures, as further described below. The loading fiber(s) 304 may be in an unloaded (non-tensioned) or loaded condition prior to the woven connector element 410 being engaged with the mating connector element 420. While only one loading fiber 304 is shown in these cross-sectional views, it should be recognized that additional loading fibers 304 are preferably located behind (or in front of) the depicted loading fiber 304. Woven connector element 410 has three bundles, or arrays, of conductors 302 woven around each loading fiber 304. The hidden-line portions of conductors 302 reflect where the woven conductors' 302 peaks and valleys are out of plane with the particular cross-section shown. Generally, a second loading fiber 304 (not shown) would be utilized in conjunction with these out-of-plane peaks and valleys. Although not shown here, conductors 302 can be placed directly against adjacent conductors 302 so that electrical conductivity between adjacent conductors 302 can be established.

FIG. 28b depicts the woven connector element 410 of FIG. 28a after being engaged with the mating connector element 420. To engage the woven connector element 410, the woven connector element 410 is inserted into cavity 422 of mating connector element 420. In certain embodiments, a front face (not shown) of the mating conductors 306 may be chamfered to better accommodate the insertion of the woven connector element 410. Upon insertion into the mating connector element 420, the loading fibers 304 are displaced to accommodate the profile of the cavity 422 and the presence of the mating conductors 306. In some embodiments, the displacement of the loading fibers 304 can be facilitated through a stretching of the loading fibers 304. In other embodiments, this displacement can be accommodated through the tightening of an otherwise slack (in a pre-engaged condition) loading fiber 304 or, alternatively, a combination of stretching and tightening, which results in a tension T being present in the loading fibers 304. As previously discussed, due to the orientation and arrangement of the loading fibers 304—conductors 302 weave, the tension T in the loading fibers 304 will cause certain normal contact forces to be present at the contact points. As can be seen in FIG. 28b, the woven connector 400 has mating conductors 306 that are alternately located on the interior surfaces (which define the cavity 422) of the mating connector element 420. This alternating contact arrangement produces alternating contacts on opposite parallel planar contact mating surfaces 308.

Instead of utilizing a flat (e.g., substantially planar) contact mating surface 308 as depicted in FIG. 28b, another embodiment uses a curved, e.g., convex, contact mating surface 308. The curvature of the contact mating surface 308 may permit improved tolerance controls for contact between the contact points of the conductors 302 and the mating conductors 306 in the normal direction. The curved surface (of the contact mating surfaces 308) helps maintain a very tightly controlled normal force between these two separable contact surfaces. The curved surface itself, however, does not generally assist in maintaining lateral alignment between the conductors 302 and the mating conductors 306. Insulating fibers (e.g., insulating fibers 104 as shown in FIG. 7) placed parallel with and interspersed between segments of conductors 302 could be utilized to assist with the lateral alignment of adjacent conductors 302. The curvature of the contact mating surface 308 need not be that significant; improved location tolerances can be realized with a relatively small amount of curvature. In some preferred embodiments, contact mating surfaces 308 having a large radius of curvature may be used to achieve some desired manufacturing location tolerances. FIG. 29 illustrates an alternative mating conductor 306 having a curved contact mating surface 308 that could be used in the woven connector 400 of FIG. 28. The curvature of the contact mating surface 308 allows for a very generous positioning tolerance during manufacturing and operation.

Referring to FIG. 29, improved location tolerances can often be achieved by utilizing contact mating surfaces 308 which have a radius of curvature R 336 that is greater than the width W 309 of the mating conductor 306. Specifically, the relationship between the lateral spacing L 332 found between two conductors 302 and the angle α 334 between the two conductors 302 and the radius of curvature R 336 of the contact mating surface 308 is given by the formula L≅αR. The minimum of the lateral spacing L 332 is set by the diameter of the conductors 302 and, thus, the lateral spacing L 332 may be tightly controlled by locating the conductors 302 directly against each other. In other words, in certain exemplary embodiments the conductors 302 are located so that no gap exists between the adjacent conductors 302. Thus, for a very low angle α 334, the required radius of curvature R 336 can then be determined. In an exemplary embodiment having an angle α 334 of 0.25 degrees and conductors 302 having a diameter of 0.005 inches, for example, a preferred contact mating surface's 308 radius of curvature R 336 would thus be on the order of about 2.29 inches. The tolerance on this is also quite generous as the angle α 334 is directly related to the radius of curvature R 336. For example, if the tolerance on the radius of curvature R 336 was set at ±1.10 inches, then the angle α 334 could vary from between 0.261 degrees and 0.239 degrees. To illustrate the benefits of using a curved contact mating surface 308, to maintain a tolerance of 0.03 degrees on the flat array embodiment of FIG. 28 would require a tolerance of 0.0000105 inches on the offset height H 324. Additionally, the introduction of curved contact mating surfaces 308 does not materially affect the overall height of the woven connectors. With a radius of curvature R 336 of 2.29 inches and a mating conductor 306 width W 309 of 0.50 inches, for example, the total height 311 of the arc would only be about 0.014 inches, i.e., the contact mating surface 308 is nearly flat.

Load balancing is an issue with multi-contact electrical connectors, and particularly so with multi-contact electrical power connectors. Load imbalances within electrical connectors can cause the connectors to burn-out and thus become inoperable. In their basic form, electrical connectors simply provide points of electrical contact between male and female conductive pins. In electrical connectors that are load balanced, the incoming currents are evenly distributed through each of the contact points. Thus for a 10 amp connector having four contact points, the connector is balanced if 2.5 amps are delivered through each contact point. If a connector is not load balanced, then more current will pass through one contact than another contact. This imbalance of electrical current may cause overloading at one of the “overloaded” contact points, which can result in localized welding, localized thermal spikes and conductor plating damage, all of which can lead to increased connector wear and/or very rapid system failure. A load imbalance can be caused by having different conductive path lengths in the connector system, high separable interface electrical contact resistance at one point (e.g., due to poor contact geometry), or large thermal gradients in the connector. An advantage of power connectors as taught by this disclosure is that they can be fully (or substantially) load balanced across many contact points. For each conductor 302 (i.e., conductive fiber), the first contact point that is to make electrical contact with the mating conductor 306 can be designed to carry the full current load that is to be allocated for that conductor 302. Subsequent contact points located along the conductor 302 are also generally designed to carry the full current load in case there is a failure (to provide electrical contact) at the first contact point. The additional contact points located downstream of the first contact point on each of the conductors 302 therefore can carry all or some of the allocated current, but their primary purpose is typically to provide contact redundancy. Moreover, as already stated, the multiple contact points help to prevent localized hot spots by producing multiple thermal pathways.

In most exemplary embodiments, the conductors 302 of a connector will generally have similar geometries, electrical properties and electrical path lengths. In some embodiments, however, the conductors 302 of a connector may have dissimilar geometries, electrical properties and/or electrical path lengths. Additionally, in some preferred power connector embodiments, each conductor 302 of a connector is in electrical contact with the adjacent conductor(s) 302. Providing multiple contact points along each conductor 302 and establishing electrical contact between adjacent conductors 302 further ensures that the multi-contact woven power connector embodiments are sufficiently load balanced. Moreover, the geometry and design of the woven connector prohibit a single point interface failure. If the conductors 302 located adjacent to a first conductor 302 are in electrical contact with mating conductors 306, then the first conductor 302 will not cause a failure (despite the fact that the contact points of the first conductor 302 may not be in contact with a mating conductor 306) since the load in the first conductor 302 can be delivered to a mating conductor 306 via the adjacent conductors 302.

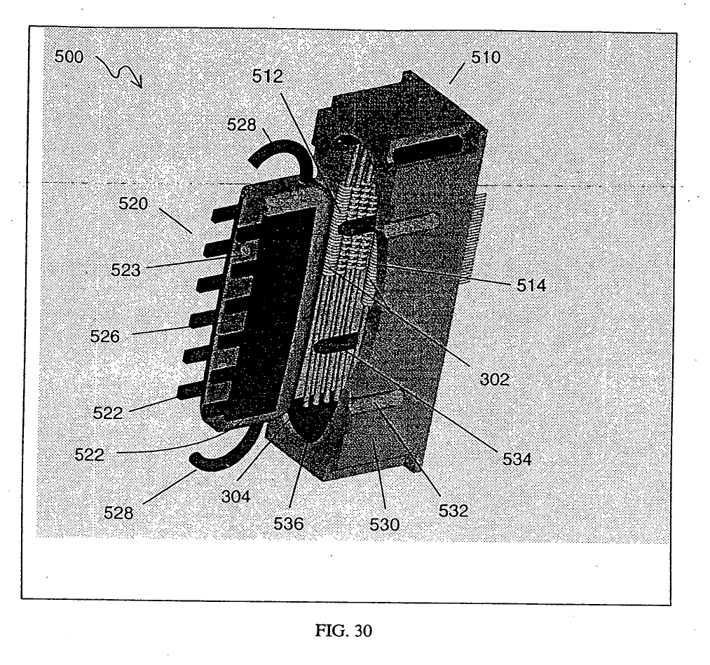

FIG. 30 illustrates an exemplary embodiment of a load-balanced multi-contact woven power connector 500. The power connector 500 includes two extended arrays, a power array and a return array. These arrays provide multiple contact points over a wide area, which can result in high redundancy, lower separable electrical contact resistance, and better thermal dissipation of parasitic electrical losses. The power connector 500 as shown is a 30 amp DC connector having a power circuit 512 and a return (ground) circuit 514. Persons skilled in the art will readily recognize that other power connectors having different arrangements and power capabilities can be constructed without departing from the scope of the present disclosure. The load capabilities of the power connector 500 can be increased by adding additional conductors 302, for example. Referring to FIG. 30, the power connector 500 comprises a woven connector element 510 and a mating connector element 520. The mating connector element 520's external housing has been omitted from these figures for clarity. The woven connector element 510 includes a housing 530, a power circuit 512, a return circuit 514, end plates 536, alignment pins 534 and a plurality of loading fibers 304. The housing 530 has several recesses 532 that can facilitate the mating of the mating connector element's external housing (not shown) to the housing 530 of the woven connector element 510. The recesses 532 may accommodate an alignment pin (not shown) or a fastening means (not shown). The power circuit 512 comprises several conductors 302 woven around several loading fibers 304 in accordance with the teachings of the present disclosure. To achieve a desired load capacity of 30 amps, the power circuit 512 may have between 20-40 conductors 302 depending upon the diameter of the conductors 302 and their electrical properties, for example.

In certain exemplary embodiments, the conductors 302 can include copper or copper alloy (e.g., C110 copper, C172 Beryllium Copper alloy) wires having diameters between 0.0002 and 0.010 inches or more. Alternatively, the conductors may be flat ribbon wires having comparable rectangular cross-section dimensions. The conductors 302 may also be plated to prevent or minimize oxidation, e.g., nickel plated or gold plated. Acceptable conductors 302 for a given woven connector embodiment should be identified based upon the desired load capabilities of the intended connector, the mechanical strength of the candidate conductor 302, the manufacturing issues that might arise if the candidate conductor 302 is used and other system requirements, e.g., the desired tension T. The conductors 302 of the power circuit 512 exit a back portion of the housing 530 and may be coupled to a termination contact or other conductor element through which power can be delivered to the power connector 500. As is discussed in more detail below, the loading fibers 304 of the power circuit 512 are capable of carrying a tension T that ultimately translates into a contact normal force being asserted at the contact points of the conductors 302. In exemplary embodiments, the loading fibers 304 may include or be formed of nylon, fluorocarbon, polyaramids and paraaramids (e.g., Kevlar®, Spectra®, Vectran®), polyamids, conductive metals and natural fibers, such as cotton, for example. In most exemplary embodiments, the loading fibers 304 have diameters (or widths) of about 0.010 to 0.002 inches. However, in certain embodiments, the diameter/widths of the loading fibers 304 may be as low as 18 microns when high performance engineered fibers (e.g., Kevlar) are used. In a preferred embodiment, the loading fibers 304 are formed of a non-conducting material. The return circuit 514 is arranged in the same manner as the power circuit 512, except that the power circuit 512 is coupled to a termination contact that can be connected to a return circuit.

The mating connector element 520 of the power connector 500 includes an external housing (not shown), an insulating housing 526, two mating conductors 522 and two spring arms 528. The mating conductors 522 are attached to opposite sides of the insulating housing 526 so that when the mating connector element 520 is engaged with the woven connector element 510, the contact points of the conductors 302 (of circuits 512 and 514) will come into electrical contact with the mating conductors 522. Insulating housing 526 serves to provide a structural foundation for the mating conductors 522 and also to electrically isolate the mating conductors 522 from each other. Insulating housing 526 has holes 523 that can accommodate the alignment pins 534 and thus assist in facilitating the coupling of the mating connector element 520 to the woven connector element 510 (or vice versa). Spring arms 528 may act to firmly secure the mating connector element 520 to the woven connector element 510. Additionally, in certain preferred embodiments, spring arms 528 also operate in conjunction with the end plates 536 of the woven connector element 510 to exert a tension load T in the loading fibers 304 of the woven connector element 510.

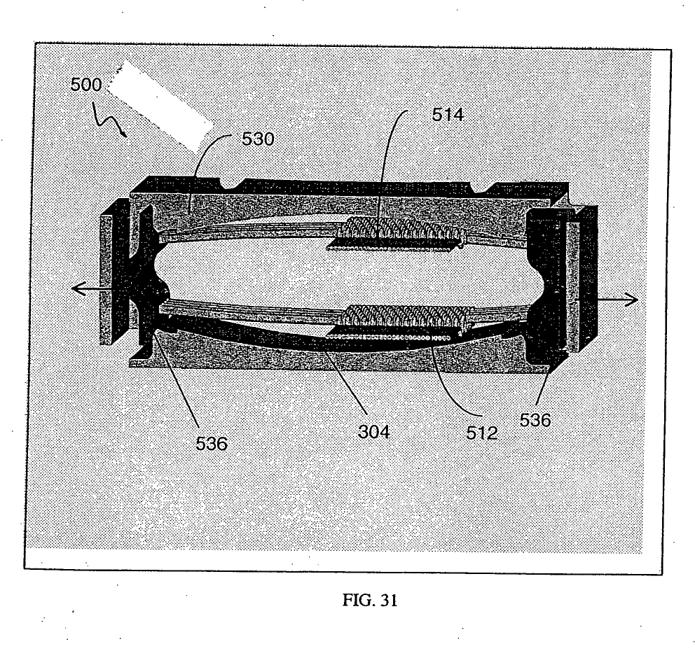

FIG. 31 illustrates an exemplary embodiment of a woven connector element 510 having floating end plates 536 that are capable of generating a tension T in loading fibers 304. FIG. 31 depicts a rear view of the woven connector element 510 of FIG. 30 with a back portion of the housing 530 removed for clarity. Loading fibers 304 are interwoven with the conductors 302 of the power circuit 512 and the return circuit 514. The ends of the loading fibers 304 are coupled to the two opposite floating end plates 536. The ends of the loading fibers 304 can be coupled to the floating end plates through a wide variety means know in the art, for example, by mechanical fastening means or bonding means. The floating end plates 536 may be allowed to float (i.e., remain unconstrained) prior to the installation of mating connector element 520 or, in an alternate embodiment, secondary spring mechanisms (not shown) coupled to the housing 530 and an end plate 536 may be used to control the lateral (e.g., outward) displacement of the end plates 536, i.e., in a direction away from the circuits 512, 514. In some exemplary embodiments, the loading fibers 304 will be in an un-tensioned state prior to the installation of the mating connector element 520. In other exemplary embodiments, however, some tensile load (which will usually be less than the tension T needed to generate a desired normal contact force) may be present in the loading fibers 304 prior to the installation of the mating connector 520. This pre-installation tensile load may be due to the presence of the secondary spring mechanisms or, alternatively, may be pre-loaded onto the loading fibers 304 when the loading fibers 304 are coupled to the end plates 536.

Upon inserting the mating connector element 520 into the woven connector element 510 (or vice versa), the spring arms 528 of the mating connector element 520 engage the floating end plates 536 of the woven connector element 510. Based upon the stiffness of the spring arms 528, the stiffness and/or elasticity of the conductors 302, the stiffness of the secondary spring mechanism (if present) and the pre-installation dimensions/locations of the spring arms 528 and the end plates 536, the end plates 536 will become displaced (move outward) to some degree because of the presence of the spring arms 528. The spring arms 528, of course, may also experience some deflection during this process. This outward displacement of the floating end plates 536 can cause a tension T to be generated in the loading fibers 304. In an exemplary embodiment, the loading fibers 304 comprises an elastic material. In such exemplary embodiments, the relative displacement of the two end plates 536 may result in a substantially equal amount of stretching in the load fibers 304. In other exemplary embodiments, spring arms 528 can be mounted directly on the floating end plates 536 of the woven connector element 510 instead of on the mating connector element 520 as depicted in FIG. 30.

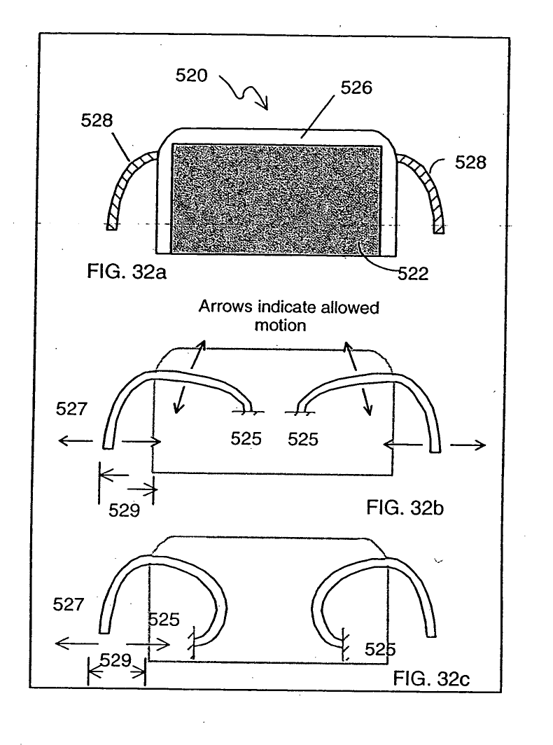

FIGS. 32a-c illustrates some exemplary embodiments of spring arms 528 that are constructed in accordance with the teachings of the present disclosure. The effective spring height 529 of the spring arms 528 can be increased by embedding a portion of the spring arm 528 within the insulating housing 526 of the mating connector element 520. It is desirable that the spring arms 528 be capable of generating a large relative deflection motion (e.g., approximately 0.020 inches) for a given load when the mating connector element 520 is inserted into the woven connector element 510. By generating a large relative motion, the manufacturing and alignment tolerances on the assembly can be loosened (e.g., the length tolerance of the loading fiber 304 could be modified from ±0.005 inches to ±0.015 inches) while still keeping the final assembled line tolerance within a specified range. FIG. 32a depicts an exemplary embodiment of spring arms 528 where little or none of the spring arm 528 is embedded into the insulating housing 526 of the mating connector element 520. FIGS. 32b-c illustrate two preferred embodiments of spring arms 528 that have a significant portion of the spring arms 528 embedded into the insulating housing 526 of the mating connector element 520. The portion of the spring arms 528 that are embedded in the insulating housing 526 should be free to move (within the insulating housing 526) except at the anchors 525, where they are fixed. The spring arms 528 of FIG. 32b essentially travel around half a circle and terminate at anchors 525, which are substantially parallel to the effective direction of tip deflection 527. The spring arms 528 of FIG. 32c essentially travel around three-quarters of a circle and terminate at anchors 525 which are substantially orthogonal to the effective direction of tip deflection 527. The spring arm 528 embodiments depicted in FIGS. 32b-c will have longer effective spring heights 529, which yield correspondingly larger tip deflection motions 527 for the same force as compared to the “short” spring arms 528 embodiment of FIG. 32a.

In certain exemplary embodiments, the spring arm 528 can include a metal or metal alloy, such as nitinol, for example, and can be a wire spring or a ribbon spring, amongst others. Other suitable materials and/or arrangements may be employed, as the present invention is not limited in this respect. Depending on the diameter of the spring arm 528 and connector 500 dimensions, multiple turns of the spring arm 528 may also be possible.

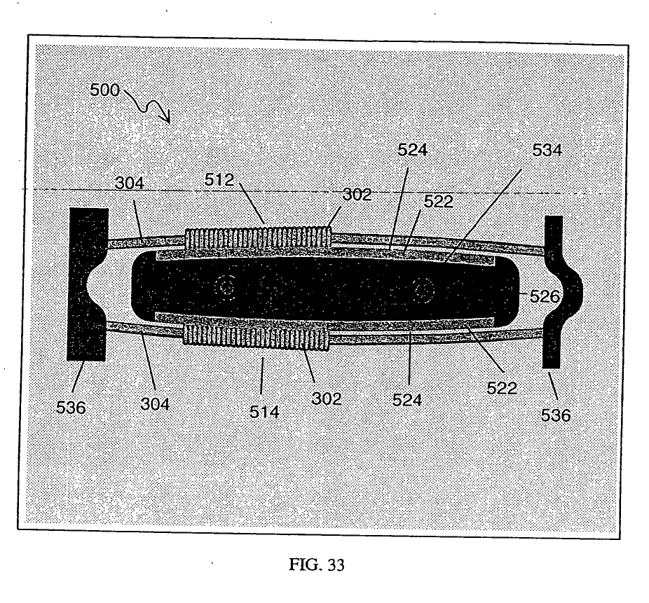

FIG. 33 is a front view of the power connector 500 after the mating connector element 520 has been engaged with the woven connector element 510. The external housing and the spring arms 528 of the mating connector element 520 and the housing 530 of the woven connector element 510, amongst other features, have been removed for clarity. As can be seen in FIG. 33, after the engagement of the mating connector element 520, the contact points of the conductors 302 of the circuits 512, 514 are in electrical contact with the contact mating surface 524 of the mating connector 522. As previously discussed, while the contact mating surface 524 can be substantially planar, in a preferred embodiment the contact mating surface 524 is defined by some radius of curvature R (not shown), e.g., R 336. In some preferred embodiments, this radius of curvature R 336 will be greater than the mating conductor's 522 width W (not shown), e.g., W 309.

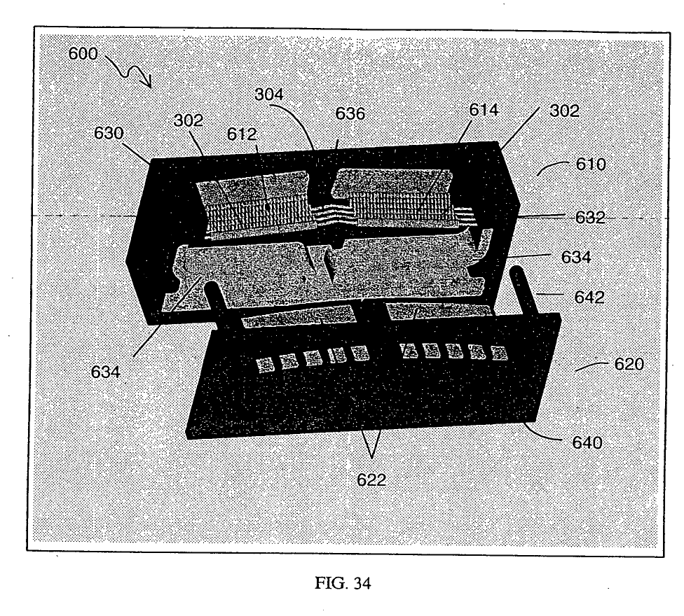

FIG. 34 illustrates another exemplary embodiment of a multi-contact woven power connector 600 that is highly balanced. The power connector 600 comprises two extended arrays, a power array 612 and a return array 614. These arrays provide multiple contact points over a wide area, which can result in high redundancy, lower separable electrical contact resistance, and better thermal dissipation of parasitic electrical losses. The power connector 600 could be a 30 amp DC connector. The power connector 600 comprises a woven connector element 610 and a mating connector element 620. The woven connector element 610 comprises a housing 630, a power circuit 612, a return circuit 614, two spring mounts 634, a guide member 636 and several loading fibers 304. The housing 630 has several holes 632 which can accommodate the alignment pins 642 of the mating connector element 620. The power circuit 612 comprises several conductors 302 woven around several loading fibers 304 in accordance with the teachings of the present disclosure. In a preferred embodiment, these conductors 302 are arranged to be self-terminating. The conductors 302 of the power circuit 612 exit a back portion of the housing 630 and may form a termination point where power can be delivered to the power connector 600. As is discussed in more detail below, the loading fibers 304 of the power circuit 612 (and return circuit 614) are capable of carrying a tension T that ultimately translates into a contact normal force being asserted at the contact points of the conductors 302. The return circuit 614 is arranged in the same manner as the power circuit 612. The loading fibers 304 of the power connector 600 comprise a non-conducting material, which may or may not be elastic. The guide member 636 is mounted to an inside wall of the housing 630 and is positioned so as to provide structural support for the loading fibers 304 and, indirectly, the power circuit 612 and return circuit 614. The ends of the loading fibers 304 are secured to the spring mounts 634. As is described in greater detail below, the spring mounts 634 are capable of generating a tensile load T in the attached loading fibers 304 of the woven connector element 610.

The mating connector element 620 of the power connector 600 comprises a housing 640, two mating conductors 622 and alignment pins 642. The mating conductors 622 are secured to an inside wall of the housing 640 such that when the mating connector element 620 is engaged with the woven connector element 610, the contact points of the conductors 302 (of circuits 612 and 614) will come into electrical contact with the mating conductors 622. Alignment pins 642 are aligned with the holes 632 of the woven connector element 610 and thus assist in facilitating the coupling of the mating connector element 620 to the woven connector element 610 (or vice versa).

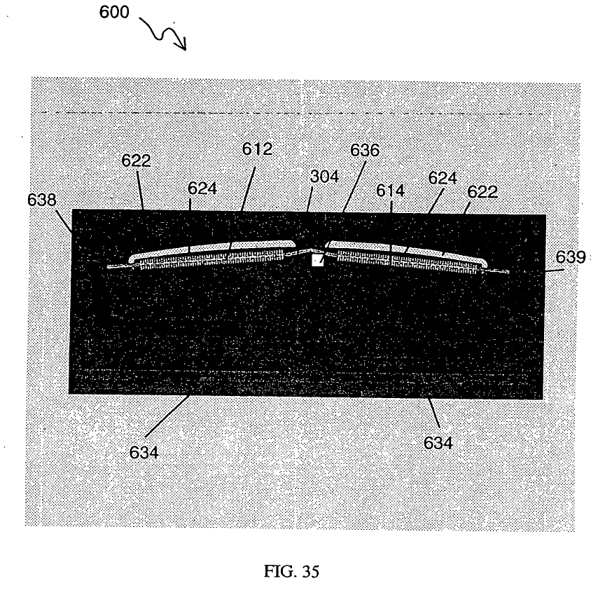

Power connector 600 has several of the same features of the power connector 500, but uses a different mechanism for producing the tension T (and, thus, the normal contact force) in the conductor 302—loading fiber 304 weave. Rather than using the floating end plates 536 of power connector 500, power connector 600 uses pre-tensioned spring mounts 634 to generate and maintain the required normal contact force between the contact points of the conductors 302 (of the circuits 612, 614) and the mating conductors 622. FIG. 35 depicts the power connector 600 after the mating connector element 620 has been engaged with the woven connector element 610. After engagement, the contact points of the conductors 302 of both the power circuit 612 and return circuit 614 are in electrical contact with the contact mating surfaces 624 of the mating conductors 622.

In a preferred embodiment, the contact mating surfaces 624 are convex surfaces that are defined by a radius of curvature R. As shown in FIG. 35, the convex contact mating surfaces 624 are located on a bottom side of the mating conductors 622, i.e., after engagement, the conductors 302 are located below the mating conductors 622. In an exemplary embodiment, the guide member 636 is positioned such that the upper potion of the guide member 636 is located above the contact mating surfaces 624. After engagement, the loading fibers 304 run from an end 638 of the first spring mount 634, against the convex contact mating surface 624 that corresponds to the power circuit 612, over the top portion of the guide member 636, against the convex contact mating surface 624 that corresponds to the return circuit 612 and then terminates at an end 639 of the second spring mount 634. In other exemplary embodiments, the contact mating surfaces 624 can be located on the top-side of the mating conductors 622, and the loading fibers 304 would therefore extend over these top-located convex contact mating surfaces 624. The locations of the end 638, guide member 636, contact mating surfaces 624 and end 639, working in conjunction with the tension T generated in the loading fibers 304, facilitate the delivery of the contact normal forces at the contact points of the conductors 302.

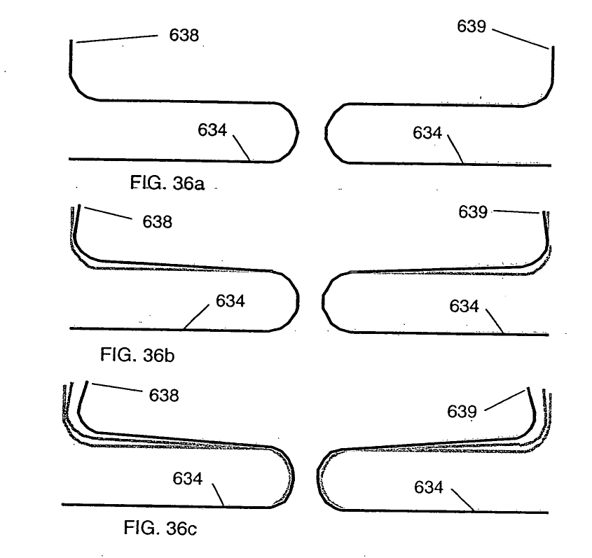

FIGS. 36a-c depicts an exemplary embodiment of a pair of spring mounts 634 that could be used in power connector 600. The loading fibers 304 have been omitted for clarity but it should be understood that the ends of the loading fibers 304 are to be attached to the ends 638, 639. Prior to engagement, the loading fibers 304 are supported by a support pin (not shown), such as the guide member 636, for example. During engagement, the loading fibers 304 are aligned with contact mating surfaces 624. FIGS. 36a-c illustrate how the spring mounts 638 function in the power connector 600. FIG. 36a illustrates the spring mounts 634 in an un-loaded state that occurs prior to the loading fibers being coupled to the ends 638, 639. Referring to FIG. 36b, to attach the loading fibers 304 to the ends 638, 639, the ends 638, 639 are slightly moved inward and the loading fibers 304 are then anchored to the ends 638, 639. Persons skilled in the art will readily recognize a wide variety of ways in which the loading fibers 304 can be anchored to the ends 638, 639, e.g., using slots, anchor points, fasteners, clamps, welding, brazing, bonding, etc. After the loading fibers 304 have been anchored to the ends 638, 639 of the spring mounts 634, a small tension force will generally be present in the loading fibers 304. Referring now to FIG. 36c, during the insertion of the mating connector element 620 into the woven connector element 610, the loading fibers 304 are pushed under the contact mating surfaces 624 (or, alternatively, pulled over the contact mating surfaces 624, if the surfaces 624 are located on the top side of the mating conductors 622) and the mating of the power connector 600 is then completed. To facilitate the engagement of the loading fibers 304 with the contact mating surfaces 624, the ends 638, 639 of the spring mounts 634 will generally undergo some additional deflection. Thus, the loading fibers 304 will be subjected to an additional tensile load so that a resultant tension T is then present in the loading fibers 304 (and, consequently, contact normal forces are present at the contact points of the conductors 302).

The electrical connectors constructed in accordance with the teachings of the present disclosure are inherently redundant. That is, if any of the loading fibers 304 of these embodiments breaks or looses tension, the remaining loading fibers 304 could continue to assert sufficient tension T so that electrical contact at the contact points of the conductors 302 could be maintained and, thus, the connectors could continue to carry the rated current capacity. In certain exemplary embodiments, a complete failure of all the loading fibers 304 would have to occur for the connector to loose electrical contact. In the case of dirt or a contaminant in the system, the multiple contact points are much more efficient at maintaining contact than a traditional one or two contact point connector. If a single point failure does occur (due to dirt or mechanical failure), then there are generally at least three surrounding local contact points which would be capable of handling the diverted current: the next contact point found in line (or previous in line) on the same conductor 302, and since each conductor 302 is preferably in electrical contact with the conductors 302 that are adjacent to it, the current can also flow into these adjacent conductors 302 and then through the contact points of these conductors 302.

The teachings of the present disclosure, furthermore, can be utilized in many woven multi-contact data connector embodiments. In designing such woven multi-contact data connector embodiments, issues that are commonly considered by those skilled in the art when designing data connectors, such as impedance matching, rf shielding and cross-talk issues, amongst others, need to be taken into consideration. In data connector embodiments, a data signal path can be established through a conductor(s) of a woven connector element and a mating conductor of a mating connector element. The primary difference between the woven data and power connector embodiments is the size of the individual circuit. In woven power connector embodiments, the contact surfaces (i.e., the contact points of the conductors and corresponding contact mating surfaces) tend to be much larger than those of the woven data connector embodiments due to the higher current requirements. The woven data connector embodiments, moreover, are more likely to contain multiple isolated circuit (signal) paths mounted on a single conductor 302—loading fibers 304 weave. This allows for a high density of signal paths in the woven data connector embodiments. Additionally, there is much more flexibility in the implementation of the data connector embodiments due to the different pin/ground/signal/power combinations that are possible in order to generate the required impedance, cross talk and signal skew characteristics.

The data connector embodiments of the present disclosure also provide advantages over traditional data connectors that use stamped spring arm contacts. First, it is easier to keep very tight tolerances at very small sizes with the woven data connectors than the traditional stamped spring arm contact methods. Second, drawn wire (e.g., for conductors 302) is available at low costs even at very small sizes, whereas comparable sized conventional stampings having similar tolerances can become quite expensive. Third, signal path stubs at the connector interfaces can be reduced or eliminated in the woven data connectors of the present disclosure. Stubs are present in a circuit when energy propagating through a part of the circuit has no place to go and tends to be reflected back within the circuit. At high frequencies, these interface stubs can produce jitter, signal distortion and attenuation, and the interaction of these stubs with other signal discontinuities in the circuit can cause loss of data, degradation of speed and other problems. The very nature of conventional fork and blade-type connector produces a stub. The length of this stub will generally depend upon the tolerance stack up of the system (e.g., connector tolerance, backplane/daughter card flatness, stamping tolerance, board alignment tolerance, etc.) and the length of the stub may vary by an order of magnitude over a single connector. With the woven data connector embodiments of the present disclosure, there are almost no stubs within the circuits at any time, from full insertion to partial insertion, due to the presence of multiple contact points along a conductor 302. Lastly, the woven data connector embodiments may be more flexible for tuning trace impedances because, in addition to ground placement, the materials that comprise the conductor 302—loading fibers 304 (and insulating fiber 104, if present) weave can be changed to obtain more flexible impedance characteristics without any major retooling of the process line.

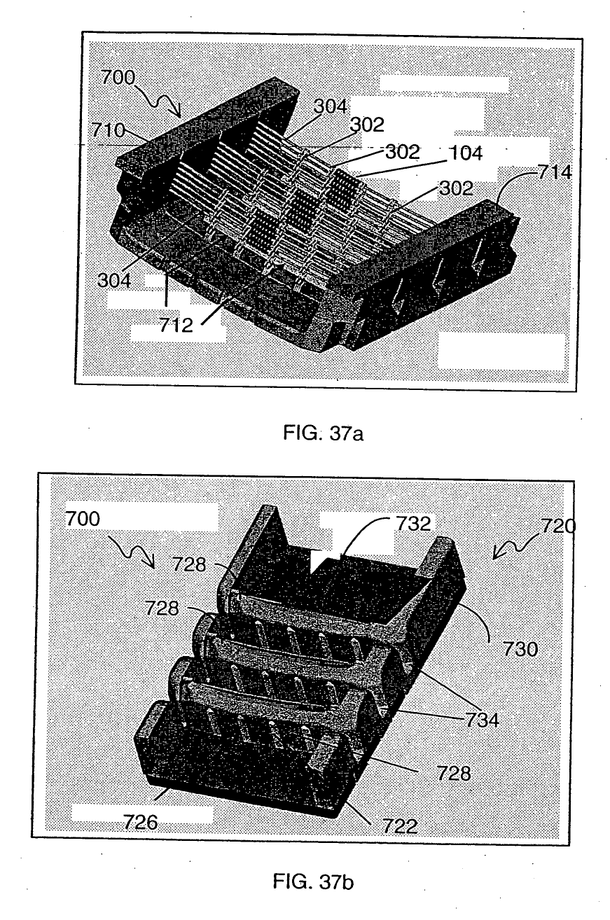

FIGS. 37a-b illustrates an exemplary embodiment of a multi-contact woven data connector 700. The data connector 700 includes a woven connector element 710 and a mating connector element 720. The woven connector element 710, as seen in FIG. 37a, comprises a housing 714, three sets of loading fibers 304 (wherein each set has six loading fibers 304) and conductors 302 that are woven onto each set of loading fibers 304. In certain exemplary embodiments, the woven connector element 710 may further include ground shields 712 and alignment pins and/or holes for receiving alignment pins. In data connector embodiments, each signal path can comprise a single conductor 302 or, alternatively, many conductors 302. However, to achieve certain desired signal path electrical properties, e.g., capacitance, inductance and impedance characteristics, in most preferred embodiments each signal path will comprise between one and four conductors 302. The conductors 302 may be self-terminating. In certain further preferred embodiments, a signal path will comprise two self-terminating conductors 302. When more than one (self-terminating or non self-terminating) conductor 302 is used to form a signal path, the conductors 302 forming the signal path should preferably be in electrical contact with each other. The conductors 302 comprising a single signal path generally will form a termination which may be located on the backside of the housing 714. The woven connector element 710 has twelve separate signal paths, four signal paths being located on each of the three sets of loading fibers 304.

The woven connector element 710 further includes insulating fibers 104 that are woven onto the loading fibers 304 between the electrical signal paths (i.e., the conductors 302). The insulating fibers 104 serve to electrically isolate the signal paths from each other in a direction along the loading fibers 304. The woven connector element 710 of FIG. 37a only depicts three sets of insulating fibers 104, a single set of insulating fibers 104 being located on each set of loading fibers 304. The sets of insulating fibers 104 have been removed for clarity. In some exemplary embodiments, additional sets of insulating fibers 104 would also be present (i.e., woven) between the other signal paths located on each set of loading fibers 304. In some exemplary embodiments, the insulating fibers 104 may be self-terminating. Furthermore, in certain exemplary embodiments the woven connector element 710 may further comprise tensioning mechanisms (not shown), e.g., spring arms, floating plates, spring mounts, etc., located at or near the ends of the loading fibers 304. These tensioning mechanisms may be capable of generating desired tensile loads in the loading fibers 304, as previously discussed.

The mating connector element 720 of the data connector 700, as seen in FIG. 37b comprises a housing 730, ground shields 732 and three insulating housings 728. The grounding shields 732 can be disposed on the backside of the insulating housings 728, i.e., on a side opposite face 726. In certain exemplary embodiments, the mating connector element 720 may further include alignment pins and/or holes for receiving alignment pins. Each insulating housing 728 has four mating conductors 722 located on a face 726. The mating conductors 722 are arranged on the faces 726 so that when the woven connector element 710 engages the mating connector element 720 (or vice versa), electrical connections between the contact points of the conductors 302 and the mating conductors 722 can be established. Thus, the signal paths of the data connector 700 are established via the conductors 302 of the woven connector element 710 and their corresponding mating conductors 722 of the mating connector element 720. The mating conductor 722 generally will form a termination point, e.g., board termination pin, which may be located on the backside of the housing 730. In exemplary embodiments, the shape and orientation of the mating conductors 722, as situated on the face 726, closely matches the shape and orientation of the conductor(s) 302, by which an electrical connection is to be established. During engagement, the faces 726 of the insulating housings 728 engage the conductors 302—loading fiber 304 weave of the woven connector element 710. In an exemplary embodiment, the faces 726 and/or the contact mating surfaces of the mating conductors 722 form a continuous convex surface. In a preferred embodiment, this convex surface can be defined by a constant radius of curvature.

In the depicted exemplary embodiment, housing 730 forms slots 734 which can accommodate the sets of loading fibers 304 when the woven connector element 710 is engaged to the mating connector element 720. After engagement, the ground shields 712 of the woven connector element 710 can help to electrically shield the mating conductors 722 of the mating connector element 720, while the ground shields 732 of the mating connector element 720 similarly can help to electrically shield the conductors 302 of the woven connector element 710. The placement and design of ground shields 712, 732 can change the electrical properties (e.g., capacitance and inductance) of the signal traces and provide a means of shielding adjacent signal lines (or adjacent differential pairs) from cross talk and electromagnetic interference (EMI). By changing the capacitance and inductance of the signal traces at particular points or regions, the impedance of the signal path can be controlled. The higher the speed of the signal, the better control that is required for impedance matching and EMI shielding. The ground planes of the data connector 700 can be on the back face of the insulating housing 728 of the mating connector element 720 and in independent metal shields 712 of the woven connector element 710. Ground pins/planes must be a conductive material and are preferably, but not necessarily, solid. In preferred embodiments, each signal path is contained within a conductive ground shield (coaxial or twinaxial) structure. This can provide the optimum signal isolation with possibilities for reducing signal attenuation and distortion. The ground shields 712, 732 of the woven connector element 710 and mating connector element 720, respectively, may or may not be in contact with each other after engagement but, preferably, some continuous ground connection should be established between the two halves of the connector 700. This can be done by forcing the ground shields 712 and 732 to contact each other or, alternatively, using one or more data pins as a ground connection between the two halves.

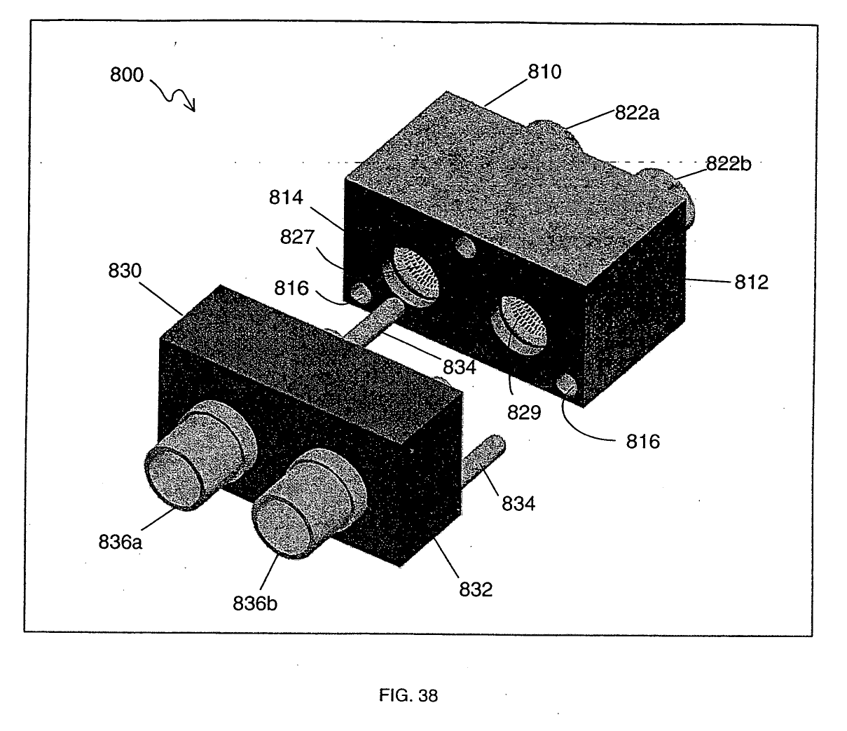

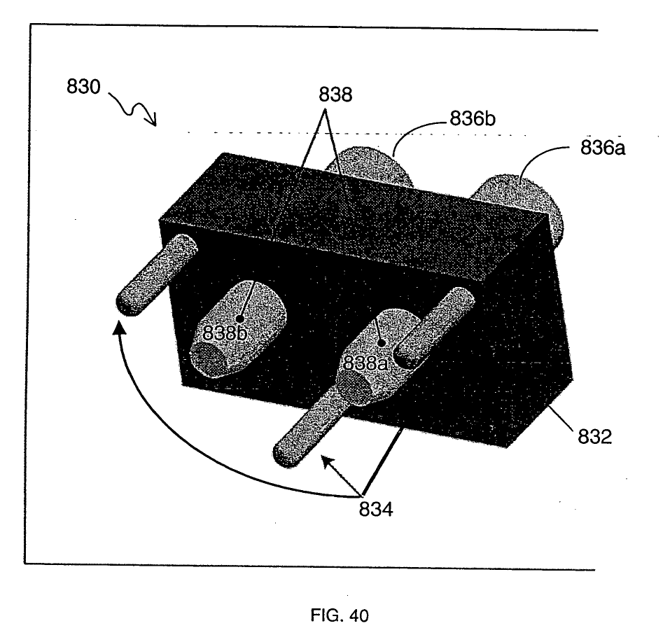

FIGS. 38-40 depict yet another exemplary embodiment of a multi-contact woven power connector. Referring to FIG. 38, power connector 800 includes a woven connector element 810 and a mating connector element 830. The woven connector element 810 comprises a housing 812, a faceplate 814, a power circuit 827, a return circuit 829 and termination contacts 822a, 822b. The power circuit 827 and return circuit 829 terminate at termination contacts 822a, 822b, respectively, which are located on the backside of the woven connector element 810. Alignment holes 816 facilitate the mating of the mating connector element 830 to the woven connector element 810 and are disposed within the faceplate 814 and the housing 812. Mating connector element 830 comprises a housing 832, alignment pins 834, mating conductors 838a, 838b (as shown in FIG. 40) and termination contacts 836a, 836b. Mating conductors 838a, 838b terminate at termination contacts 836a, 836b, respectively, which are located on the backside of the mating connector element 830.

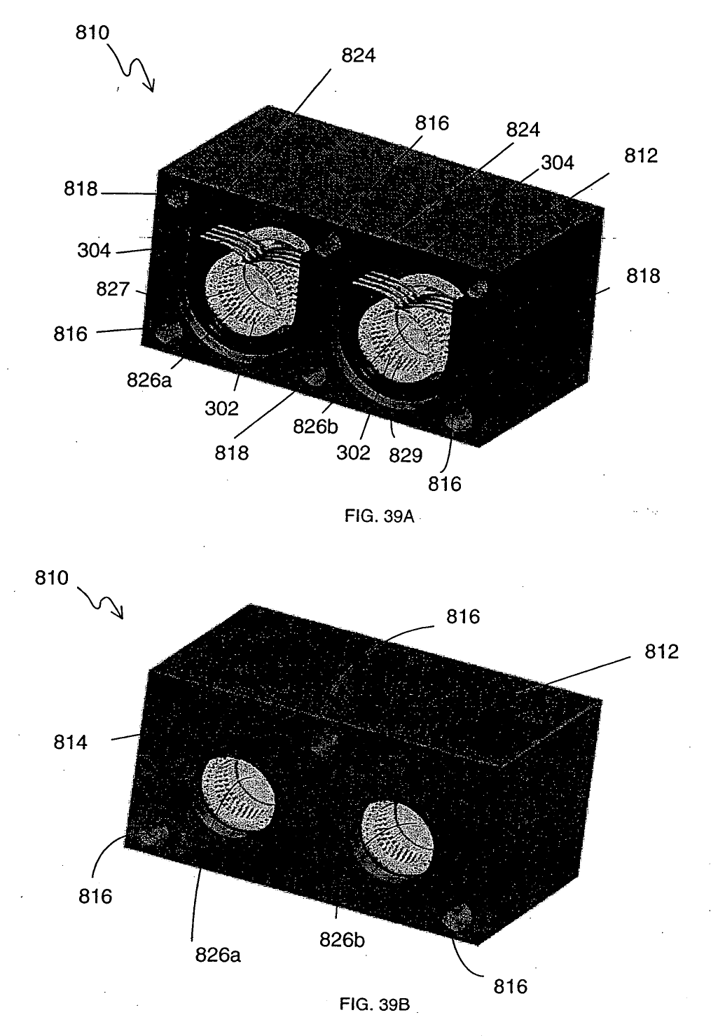

The woven connector element 810 of the power connector 800 is shown in greater detail in FIGS. 39a-b. FIG. 39a shows the woven connector element 810 with the faceplate 814 removed, while FIG. 39b shows the woven connector element 810 with the faceplate 814 installed. As seen in FIG. 39a, in addition to the alignment holes 816, woven connector element 810 also includes holes 818 which can facilitate the installation of the faceplate 814 onto the housing 812. The woven connector element 810 further includes several loading fibers 304 and several tensioning springs 824. In exemplary power connector 800, different sets of loading fibers 304 and tensioning springs 824 are utilized on the power circuit 827 and return circuit 829 sides of the woven connector element 810. The power circuit 827 comprises several conductors 302 which are woven onto several loading fibers 304 in accordance with the teachings of the present disclosure. The return circuit 829 similarly comprises several conductors 302. The conductors 302 of the return circuit 829 are woven onto several loading fibers 304. In a preferred embodiment, the conductors 302 of the power circuit 827 and the return circuit 829 are self-terminating. In the depicted exemplary power circuit 827, the conductors 302 of the power circuit 827 are each woven onto four loading fibers 304 while the conductors 302 of the return circuit 829 are each woven onto four different loading fibers 304. The ends of the loading fibers 304 of the power circuit 827 side of the woven connector element 810 are coupled, i.e., attached, to tensioning springs 824. In certain exemplary embodiments, the tensioning springs 824 of the woven connector element 810 surround the outside of the weaves that are made from conductor 302 and loading fiber 304. In other embodiments, however, the tension springs 824 need not surround the weaves. In a preferred embodiment, each loading fiber 304 is coupled to a separate independent tension spring 824, e.g., a first loading fiber 304 is coupled to a first tensioning spring 824, a second loading fiber 304 is coupled to a second tensioning spring 824, etc. The ends of the loading fibers 304 of the return circuit 829 side of the woven connector element 810 are similarly coupled to independent tensioning springs 824. By independently coupling the loading fibers 304 to separate tensioning springs 824, the power connector 800's electrical connection capabilities become more redundant and resistant to failure.

As depicted in the exemplary embodiment of FIGS. 39a-b, the conductors 302 of the power circuit 827, when woven onto the corresponding loading fibers 304, form a woven tube having a space 826a disposed therein. When woven onto the corresponding loading fibers 304, the conductors 302 of the return circuit 829 form a woven tube having a space 826b disposed therein. In most exemplary embodiments, the cross-sections of the woven tubes are symmetrical. In certain exemplary embodiments, such as woven connector element 810, for example, the cross-sections of the woven tubes are circular.

FIG. 40 shows the mating connector element 830 of FIG. 38 from an opposite view. Referring to FIG. 40, the mating connector element 830 includes mating conductors 838a, 838b. Mating conductors 838a, 838b terminate at termination contacts 836a, 836b, respectively, which are located on the backside of the mating connector element 830. In certain exemplary embodiments, the mating conductors 838a, 838b are rod-shaped (e.g., pin-shaped) and have contact mating surfaces that are circumferentially disposed along the mating conductors 838a, 838b. The mating conductors 838a, 838b are appropriately sized (e.g., length, width, diameter, etc.) so that, upon engaging the mating conductor element 830 to the woven connector element 810 (or vice versa), electrical connections between the conductors 302 of the power circuit 827 and the return circuit 829 and the contact mating surfaces of the mating conductors 838a, 838b, respectively, can be established. In certain exemplary embodiments, the diameters of the mating conductors 838 range from approximately 0.01 inches to approximately 0.4 inches.

As has been discussed herein, contact between the conductors 302 and the contact mating surfaces of the mating conductors 838 can be established and maintained by the loading fibers 304. For example, when mating conductor 838a of the mating conductor element 830 is inserted into the space 826a of the power circuit 827 (of the woven connector element 810), the mating conductor 838a causes the weave of the conductors 302 and loading fibers 304 of the power circuit 827 to expand in a radial direction. In doing so, the weave expands to a sufficient degree that the ends of the loading fibers 304 which are attached to the tensioning springs 824 are pulled closer together. This forces the tensioning springs 824 to deform elastically and tension is produced in the loading fibers 304 which thus results in the desired normal contact forces being exerted at the contact points of the conductors 302. Similarly, when mating conductor 838b of the mating conductor element 830 is inserted into the space 826b of the return circuit 829, the mating conductor 838b causes the conductor 302/loading fiber 304 weave of the return circuit 829 to expand in a radial direction. In the power connector 800 embodiment, the tensile loads within the loading fibers 304 are generated and maintained by the elastic deformation of the tensioning springs 824; when the weave expands, the loading fibers 304 are pulled by the tensioning springs 824, and thus are placed in tension. However, as previously shown, in certain embodiments, the connector systems do not need to utilize tensioning springs, spring mounts, spring arms, etc. to generate and maintain the tensile loads within the loading fibers.

When the mating connector element 830 is being engaged with the woven connector element 810, the faceplate 814 of the woven connector element 810 may assist in properly aligning the mating conductors 838a, 838b with the spaces 826a, 826b, respectively, of the woven connector element 810. The faceplate 814 also serves to protect the weaves of the woven connector element 810. To further facilitate the insertion of the mating conductors 838a, 838b into spaces 826a, 826b, the ends of the mating conductors 838a, 838b may be chamfered.

The use of rod-shaped mating conductors 838 with corresponding tube-shaped weaves allows the power connector 800 to become more space efficient, in terms of number of electrical contact points per unit volume, for example, than is generally possible with other types of multi-contact woven power connectors. The utilization of this arrangement, moreover, allows for the compact incorporation of tensioning springs that surround the weaves, which provides the longest length spring with the largest deflection under load for such a small package area. Furthermore, since the radius of the rod-shaped mating conductors 838a, 838b can be made quite small, as compared to the woven power connector systems having other shapes, the tension needed within loading fibers 304 to generate the desired normal contact force at the contact points can thus be lowered. For these reasons, power connector 800, for example, can achieve a power density that is about twice that of the power connectors 500, 600 while maintaining the same low insertion force and number of multiple redundant contacts.

The power connector 800 of FIGS. 38-40 is configured as a cable-to-cable connector and hence has a longer housing assembly, i.e., housing 812 and 832. Board-to-board power connectors can be arranged identically to the power connector 800 as shown, but with shorter housings since such connector housings do not have to be designed to withstand the forces that are exerted by the cables.

Power connector 800 includes a power circuit 827 and a return circuit 829. In accordance with the teachings of the present disclosure, however, in other embodiments the woven connector element may only comprise power circuits. Thus, in some embodiments, the return circuit 829 of woven connector element 810, for example, is replaced with a power circuit 827. In yet other embodiments, the woven connector element may include three or more power circuits. Such embodiments may also further include one or more return circuits. By having more than one power circuit being located within the woven connector element, power can be transferred across the power connector in a distributed fashion. By using a multiple-power circuit connector, the individual loads being transferred across each power circuit of the connector can be lowered (as compared to a single power circuit embodiment) while maintaining the same total power load capabilities across the connector.

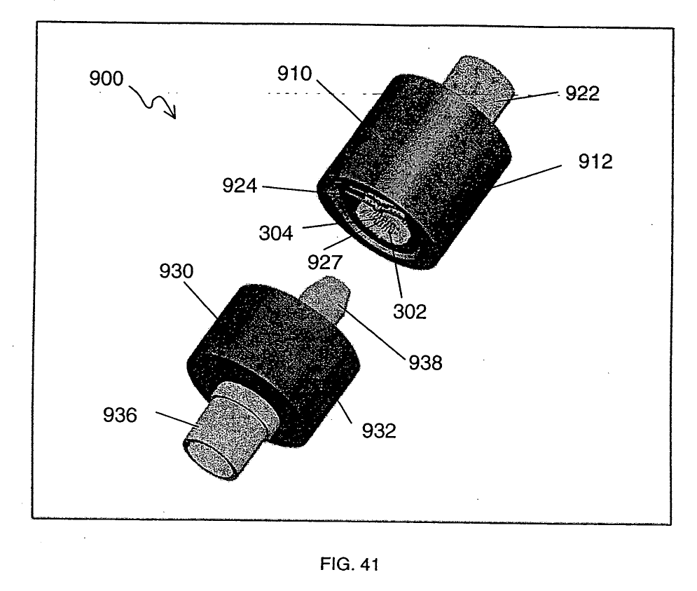

FIG. 41 depicts a further exemplary embodiment of a multi-contact woven power connector in accordance with the teachings of the present disclosure. The power connector 900 of FIG. 41 includes a woven connector element 910 and a mating connector element 930. The woven connector element 910 comprises a housing 912, an optional faceplate (not shown), several conductors 302, loading fibers 304 and tensioning springs 924, and a termination contact 922. The conductors 302 form a power circuit 827 that terminates at the termination contact 922 that is located on the backside of the woven connector element 910. The ends of the loading fibers 304 are attached to the tensioning springs 924. In a preferred embodiment, each loading fiber 304 is attached to a separate independent tension spring 924. Conductors 302 are woven onto the loading fibers 304 to form a woven tube having a space disposed therein. However, unlike the woven connector element 810 of connector 800, woven connector element 910 only includes a single weave, e.g., woven tube. Thus, the woven connector element 910 only has a single power circuit 927; woven connector element 910 does not include a return circuit.

Mating connector element 930 includes a housing 932, a mating conductor 938 and a termination contact 936. Mating conductor 938 terminates at termination contact 936, which is located on the backside of the mating connector element 930. The mating conductor 938 is rod-shaped and has a contact mating surface circumferentially disposed along its length. The mating conductor 938 is appropriately sized so that when the mating conductor element 930 is coupled to the woven connector element 910, electrical connections between the conductors 302 of the power circuit 927 and the contact mating surfaces of the mating conductors 938 can be established. Specifically, when mating conductor 938 of the mating conductor element 930 is inserted into the center space of the woven tube of the woven connector element 910, the mating conductor 938 causes the weave of the conductors 302 and loading fibers 304 to expand in a radial direction. In doing so, the weave expands to a sufficient degree that the ends of the loading fibers 304 which are attached to the tensioning springs 924 are pulled closer together. This forces the tensioning springs 924 to deform elastically and tension is produced in the loading fibers 304. With the appropriate amount of tension being present within the loading fibers 304, the desired normal contact forces are exerted at the contact points of the conductors 302 that make up the power circuit 927.

In certain embodiments, power connector 900 having a single power circuit 927 without a return circuit, could be used as a “power cable” to “bus bar” connector. Persons of ordinary skill in the art, however, will readily recognize that power connector 900 may be used for a wide variety of other connector applications.

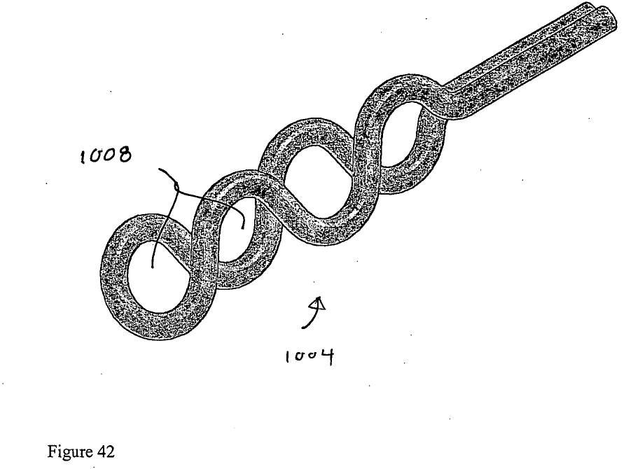

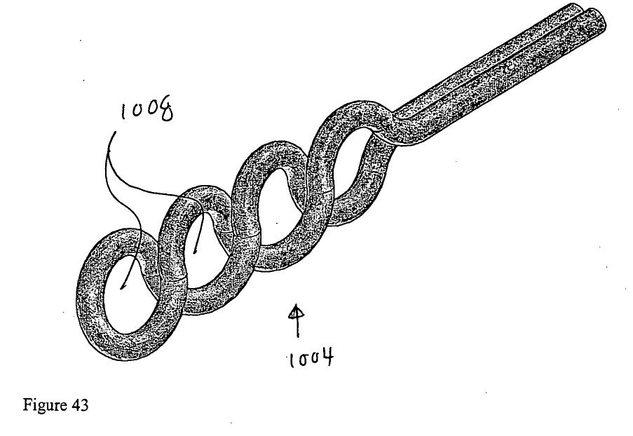

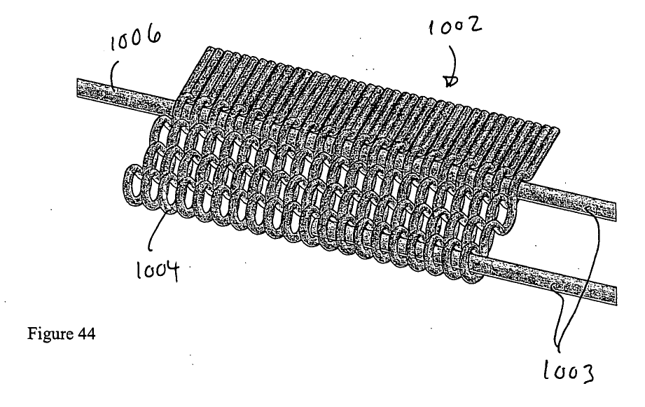

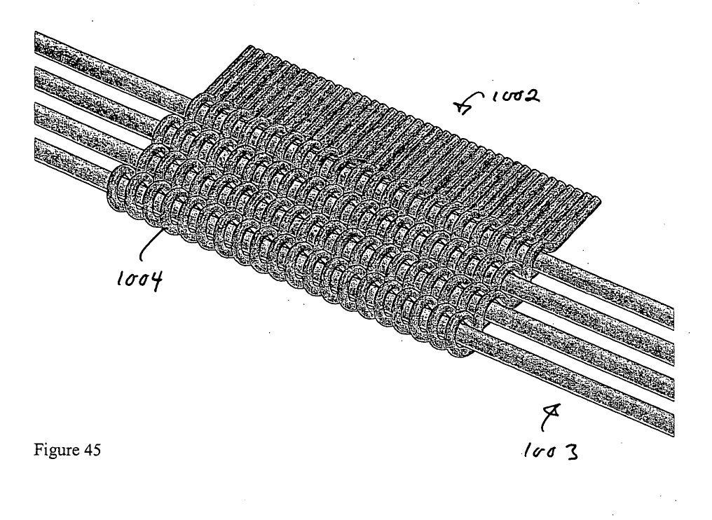

Many of the woven connectors described herein are formed from two sets of strands 1002, 1003 (the term ‘strand’ is used interchangeably herein with the term ‘fiber’). The two sets of strands are woven together by first shaping passageways 1008 in strands of the first set 1002, thereby creating formed strands 1004, like those depicted in FIG. 42 or 43. The formed strands 1004 are grouped together and retention or loading strands 1006 from the second set 1003 are inserted into the passageways 1008 to form a weave, as shown in FIGS. 44 and 45. One or more strands of the first set may be formed of suitable, conductive materials, such as copper or copper alloys. The conductive strands may be coated with any suitable material, such as gold. It should be appreciated that not all strands of the first set need be conductive. Preferably, the loading strands are non-conductive.

The woven electrical connectors can be manufactured through a process including the acts of 1) forming the first set of strands so as to produce passageways and 2) inserting loading strands into the passageways. Thereafter the ends of the formed strands may be trimmed. The formed strands may be terminated to a conductor, and the ends of the loading strands may be terminated to a feature in the connector. Although in the preferred process the steps are performed in this order, they may be performed in different orders, as the invention is not limited in this respect. In some embodiments, additional processing may also be performed. For instance, some embodiments include the additional acts of loading the connector into a housing, and quality testing the construction of the connector. In other embodiments some of these acts mat be eliminated altogether. Also, in the preferred embodiment, each of the aforementioned acts are performed on a separate fixture located in its own work station. However, in other embodiments, single fixtures or work stations are used to accomplish multiple processes. Each of these acts and variations thereof are described in greater detail below.

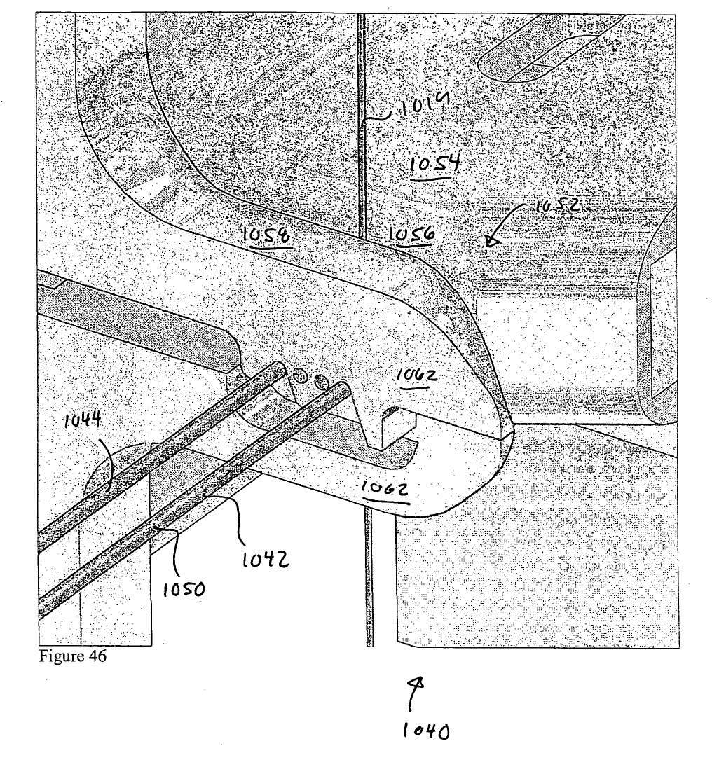

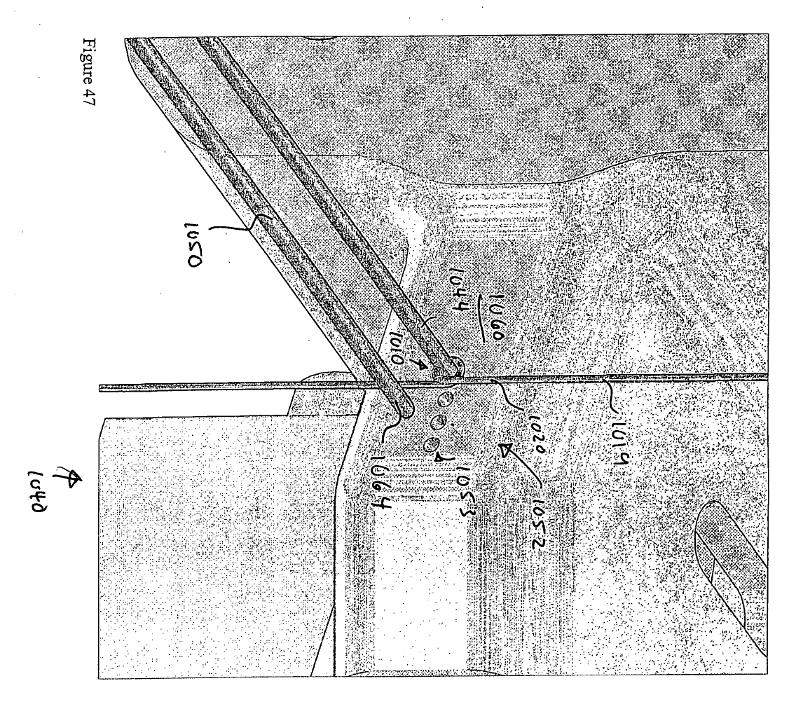

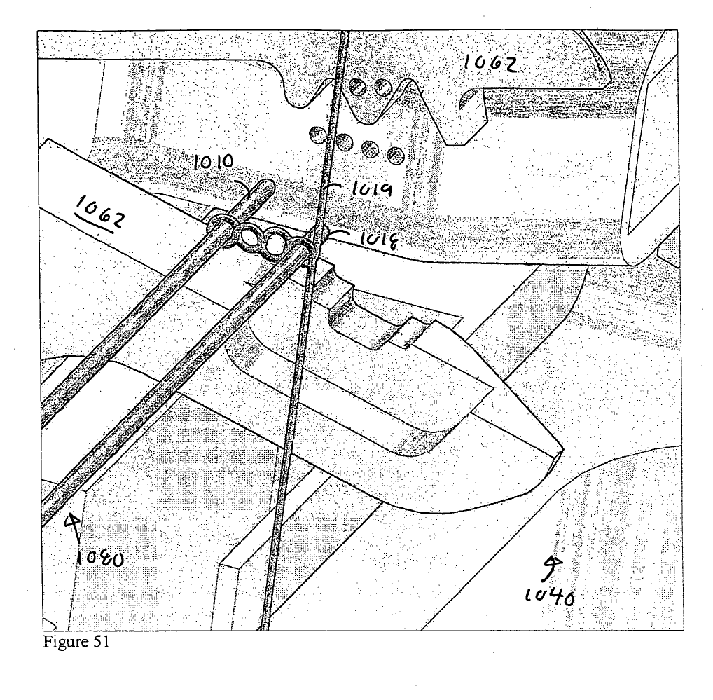

FIGS. 46-51 show, in various stages of operation, a forming fixture 1040 used to shape the first set of strands (e.g. the conductive strands). Passageways 1008 are created by plastically deforming the strands about pins 1042, or other features, shaped at least like portions of the passageways 1008 that are being formed. The illustrated forming fixture includes a work area 1052 between a left hand die 1054 and a right hand die 1058 where the forming takes place. Four pins 1044, 1046, 1048, 1050, shaped substantially like the four cylindrical passageways that are to be formed are capable of moving into and out of the work area as needed. The second and third pins 1046, 1048 extend from a surface 1056 on the left hand die facing the working area while the first and fourth 1044, 1050 pins extend from a surface 1060 on the right hand die 1058 that faces the work area from a direction opposite the surface of the left hand die (right hand die is not shown in FIGS. 47, 48, 49 and 50 to allow a clearer view of the work area). Of course, the present invention is not limited in this respect, as the pins may extend from different dies. Each of the die surfaces provide lateral guides for the strand during the forming process and each have recesses 1053 for accepting and supporting ends 1064 of pins that extend from the opposite surface. The right hand die, as shown in FIGS. 46 and 51, comprises of jaws 1062 that grasp the first and fourth pins 1044, 1050 when closed.

Before forming begins, a strand 1019 is cut to length from a spool of material, and is typically cut so that it has extra length to facilitate handling during the forming process. After being cut, the strand is loaded into the fixture by placing each of its ends 1021 into grips located on movable, forming arms (not shown). The strand is then positioned in the work area by moving the forming arms so that roughly the midpoint 1020 of the strand passes adjacent the first pin. The storage magazine, along with the attached first forming pin is then advanced into the work area while keeping the end 1021 of the fourth forming pin 1050, which is slightly shorter than the first pin 1044, out of the work area so as not to interfere with the forming of the first passageway.

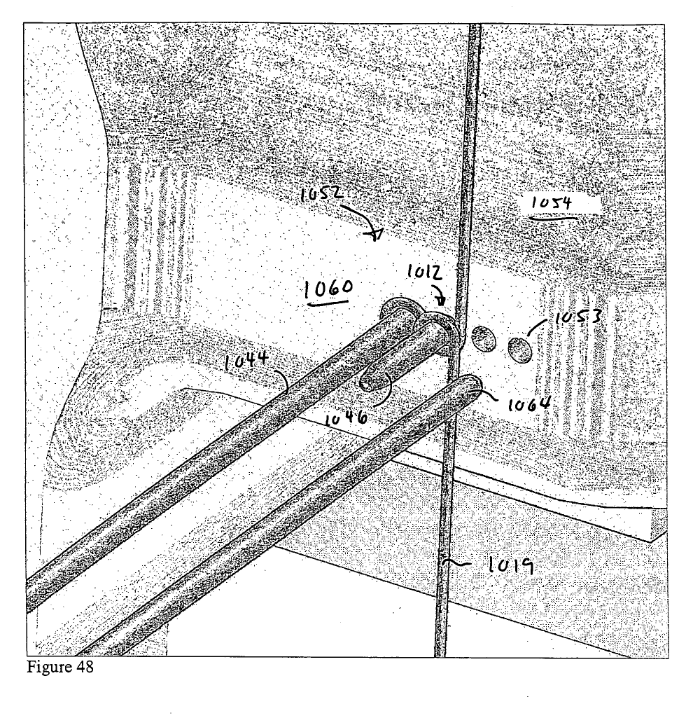

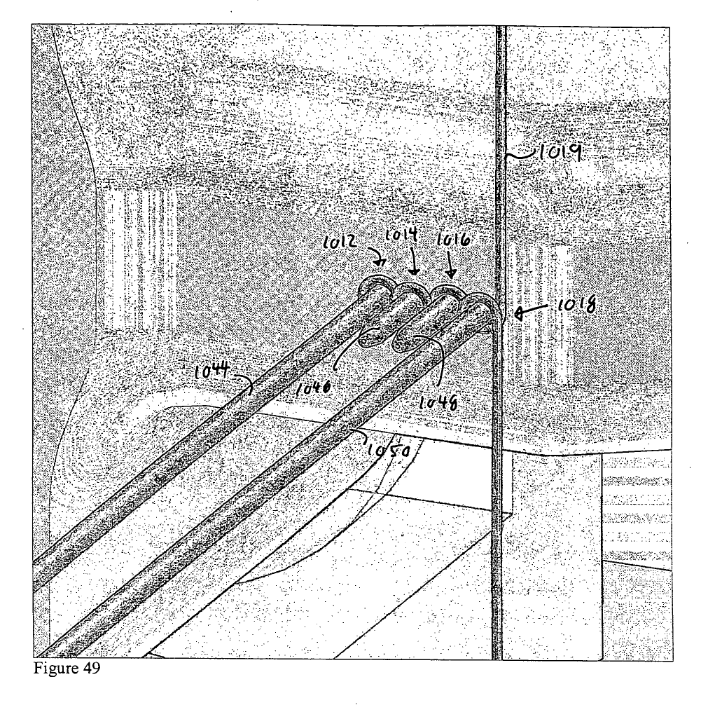

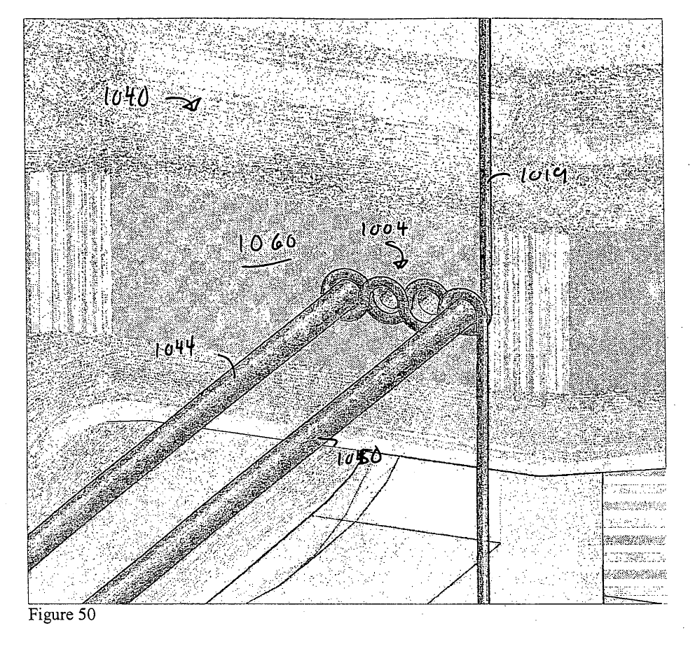

The forming process is then begun. First, the forming arms are rotated in opposite directions to wrap the mid section 1020 of the strand about the first forming pin 1044, leaving the strand as shown in FIG. 47. At this point, each of the grips on the forming arms have effectively traded positions, although they are slightly closer to one another to compensate for the material wrapped about the first pin, and are also translated slightly relative to the work area to compensate for the distance traversed when the strand was wrapped about the first pin. The second forming pin 1046 is then extended from the left hand die 1054 and into the work area, as shown in FIG. 48. The forming arms are rotated back toward their initial position (again compensating for the reduced amount of working material in the strand) to wrap the strand about the second forming pin to shape the second passageway. The process continues as the forming arms rotate once again to shape the third passageway 1014 after the third pin 1048 is extended into the work area from the left hand die 1012. Next, the fourth pin is extended into the work area. To complete the forming process, the grips are then rotated to form the fourth passageway 1016, leaving the formed strand as shown in FIG. 49.

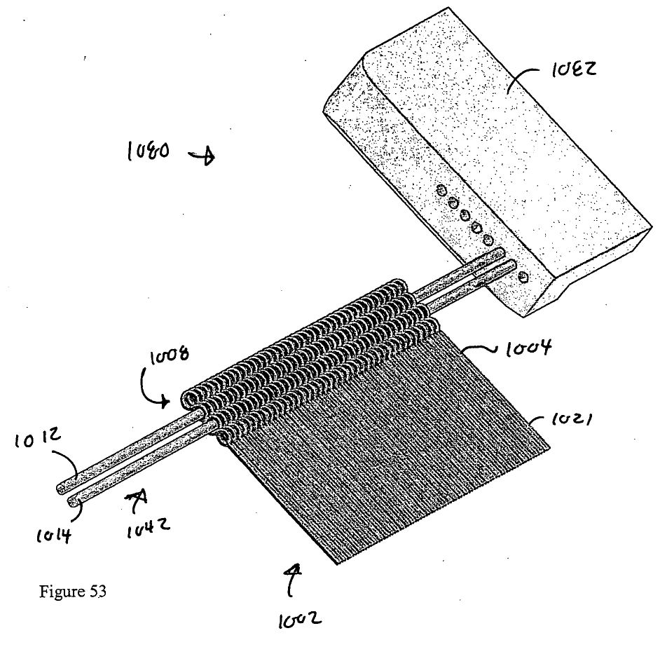

In one illustrative embodiment, the first and fourth pins are attached to the base 1082 of a storage magazine 1080, similar to the magazine shown in FIG. 53, which has pins 1042 located in the second and third positions. The storage magazine 1080 may be moved as a unit, toward and away from the work area to move the first and fourth pin into the work area as necessary. In such an embodiment, the fourth pin 1050 may be slightly shorter than the first pin 1044, so the first pin can be extended into the work area without the fourth pin. When the fourth pin is required in the forming process, the storage magazine is advanced further toward the work area, which extends the first pin further into the corresponding recess 1053 of the left hand die and also brings the fourth pin into the work area. The storage magazine may also be used to transfer the formed conductive strand away from the forming fixture 1040 for subsequent operations, or to store them in inventory for later use.

After forming, the strand is transferred away from the work area to allow additional strands to be shaped. To transfer the formed strand, the second and third pins 1046, 1048 are retracted into the left hand die, leaving the formed strand 1004 as shown in FIG. 50. Here the formed strand is held only by the first and fourth pins of the storage magazine. The jaws 1062 that comprise the right hand die are then opened, releasing the first and fourth pins of the storage magazine. The storage magazine is then moved away from the work area. At this point, the strand may be removed from the first and fourth pins to be transferred to a subsequent work station, or to storage. The jaws of the right hand die are then closed and the process is repeated to form an additional strand.

In one illustrative embodiment, the storage magazine may be used to accumulate formed strands until a desired quantity are shaped, after which they may be transferred to a subsequent work station. In this manner, after a strand is formed and the jaws of the right hand die are opened, the storage magazine is retracted until the formed strand resides on a side of the jaws opposite to the work area. The jaws are then closed and the forming process is repeated. As the storage magazine 1080 is advanced to move the first or fourth pins 1044, 1050 into the work area, the first and fourth pins are passed through the recesses in the jaws of the right hand die. As the first or fourth pins are moved toward the work area, the formed strand contacts the outermost surface of the right hand die and is pushed further onto pins of the storage magazine towards the base. Formed strands are continually loaded onto the storage magazine in this manner until the magazine is full of formed strands 1004, or otherwise until a desired number of strands have been shaped. After the storage magazine is full, it is moved from the forming fixture 1040 so the shaped strands can be taken to a subsequent operation, or stored in inventory as desired.

The fixture shown in FIGS. 46-51 is used to form a strand for one particular connector; however, other strands can be formed using this fixture 1040 and the above described methods, or variations thereof. While the strands 1004 shown in FIGS. 46-51 are substantially circular in cross section, others, like the substantially flat strands shown in FIGS. 14, 16a, 16b, 17a, and 17b can also be formed using the above described methods and fixture. Additionally, the fixture 1040 can form strands 1004 so they are twisted about themselves between each passageway, as shown in FIG. 43. The strands may also be formed with more or fewer passageways 1008 than the four that are illustrated. The passageways may be shaped to have a larger or smaller substantially circular cross section, or even of a non-circular cross section, such as an oblate cross section, a rectangular cross section, and the like. The distance between the passageways may also be altered. In one embodiment, the distance between the passageways is greater than the diameter of a strand. Further, the spacing need not be equal, as a varying spacing may be preferred in some embodiments. The passageway may have non-circular upper and lower surfaces, such as a flat surface, to form the electrical contact points of the connector. Although the strands 1004 shown in FIGS. 46-51 are self terminating, strands that are not self terminated, like those shown in FIGS. 14, 16a, 16b, 17a, 17b, or 18, for example, can also be formed. In such a case, the passageways will not be completely enclosed, but will rather only be present as bends in the strand. Some formed strands may also be wrapped around the first pin 1044 two or more times before wrapping about subsequent pins to provide greater contact area about the first passageway. Similarly, in other embodiments, the strands may be wrapped any number of times about any of the forming pins 1042.

Modifications can be made to the fixture of FIGS. 46-51 to provide for any of the above described passageway or strand variations. Also, other embodiments of the fixture may have features to manufacture connectors with any of these variations and others described herein, as the invention is not limited in this respect. By way of example, the pins 1042 may be sized differently, positioned differently or can be shaped with different cross sections to form passageways that are sized differently, spaced differently or that have different cross sections. The forming arms may rotate relative to the work area about an axis perpendicular to the pins, so that they can impart a twist when forming the strands. Pins may be added, or removed from either die of the fixture to accommodate strands with more or fewer than four passageways. In some embodiments, only one forming arm may move relative to the work area to form the passageways, instead of two forming arms moving as described above. Such an embodiment may prove particularly useful when forming strands that are not self terminating, like those shown in FIGS. 14, 16a, 16b, 17a, 17b, or 18.

Other embodiments of the fixture and method described may also be used to shape the same formed strand shown in FIGS. 46-51. For instance, the first forming pin 1044 does not need to be retractable, but rather may exist permanently within the work area in some embodiments, to simplify the fixture. Still, in other embodiments, the pins may be introduced into the work area along a direction perpendicular to the passageways being formed instead of being extended into the work area in a direction parallel to the passageways. In such an embodiment, additional pins are moved into the work area along the same path until they are positioned for forming. The strand is then wrapped about the pin in the manner described above.

Multiple strands 1004 can also be shaped on the forming fixture before they are transferred away from the work area. For instance, the forming arms of some fixtures may be able to grasp and form multiple strands at the same time about the same set of pins. In other embodiments, multiple strands 1004 may be formed in a serial manner about the same set of pins 1042 before any of the strands are transferred out of the work area. In this case, the work area may be wider and the pins may extend into the work area only as required to hold strand(s) or as necessary to form a given portion of a strand.

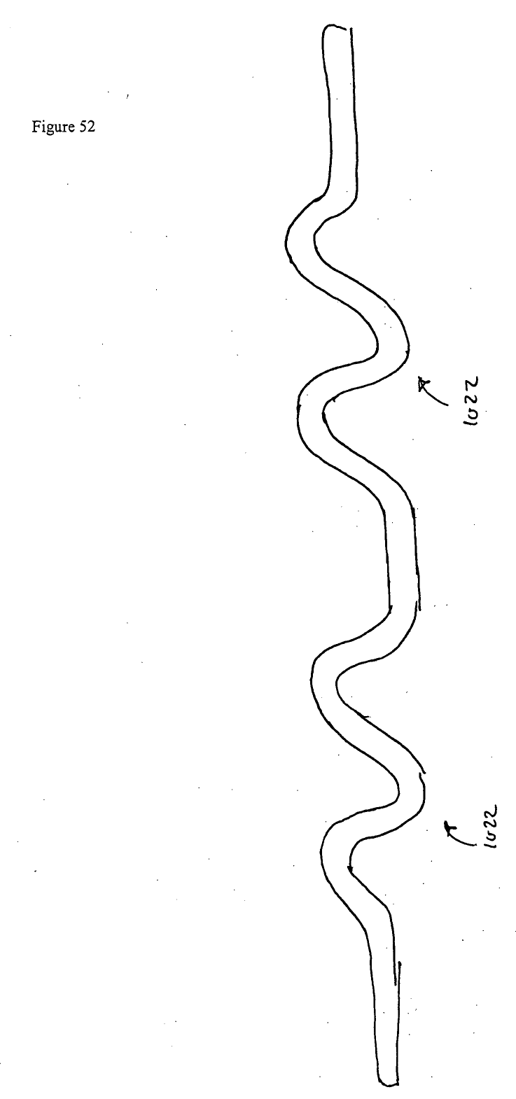

Other methods and fixtures may also be used to form strands simultaneously, for instance, some high volume applications may use a roll-forming die to form passageways in the strands. In such cases, one or more strands 1019 are rolled between two opposed dies that form two sets of corrugations 1022 in each strand. The first set and second set of corrugations 1022 being separated by a portion without corrugations, as shown in FIG. 52. After roll forming, the strands are folded such that corrugations overlap to form passageways 1008, much like those formed from the process shown in FIGS. 46-51.

After the storage magazine is full or has an amount of formed strands required for a particular connector, it is moved away from the forming fixture to subsequent work stations for further processing. The storage magazine 1080, as shown in FIG. 53, has a base 1082 and two pins 1042, much like the storage magazine previously described with respect to FIGS. 46-51, except that the storage magazine of FIG. 53 has pins positioned to fit within a second and third passageway 1012, 1014. Although not necessary for most embodiments, the formed strands 1004 can be transferred from a first magazine to a second magazine during processing by inserting the pins 1042 of the second magazine into vacant passageways of the formed strands. To complete the transfer, the second magazine is then pulled away from the first magazine while the strands are held onto the pins of the second magazine.

While in the preferred embodiment the storage magazine 1080 uses pins 1042 to hold the formed strands 1004 in place, other embodiments may hold the formed strands in other ways. Some embodiments of the magazine may have a base plate and an upper plate that sandwich the formed strands to hold them together. Some of these embodiments may have corrugations or other suitable formations in one or both of the plates that are adapted to mate with exterior features of the formed strands. End plates may also be used to prevent the formed strands from sliding along the axis of the passageways and off of storage magazine. The end plates may have holes aligned with each passageway to allow strands of the second set to be inserted through the passageways while the strands are held by the transfer magazine.

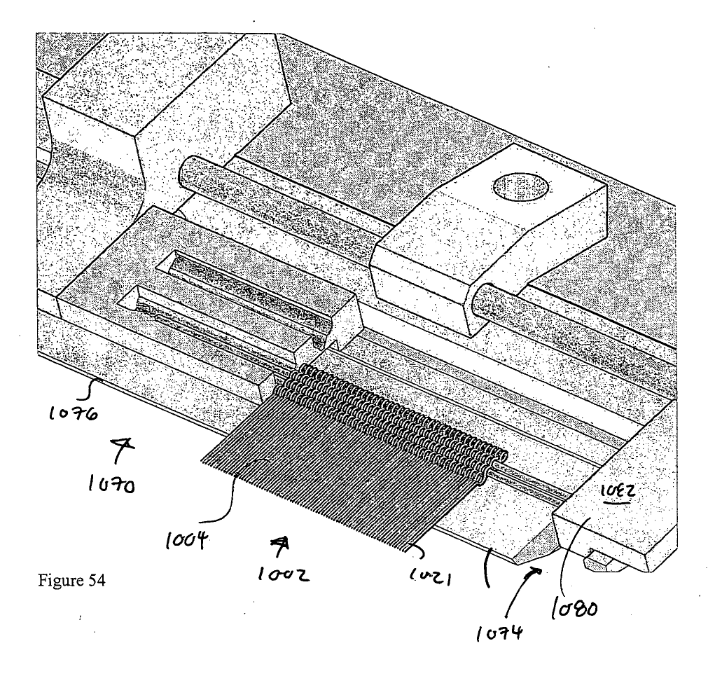

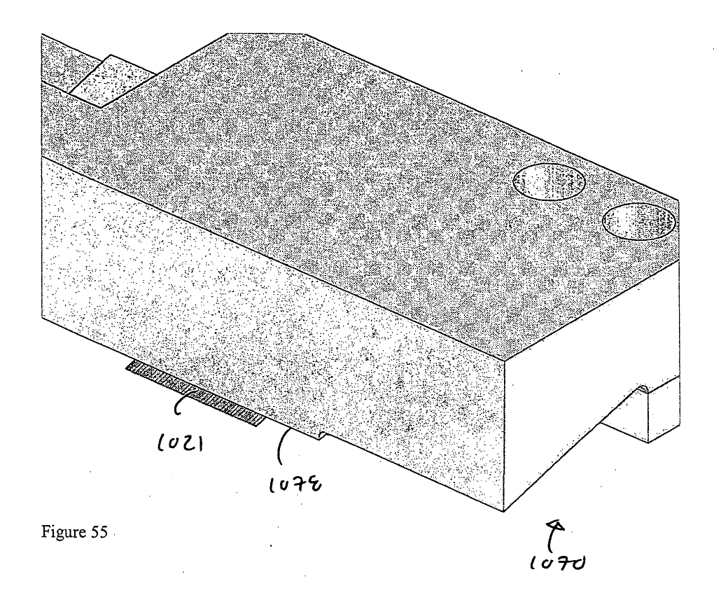

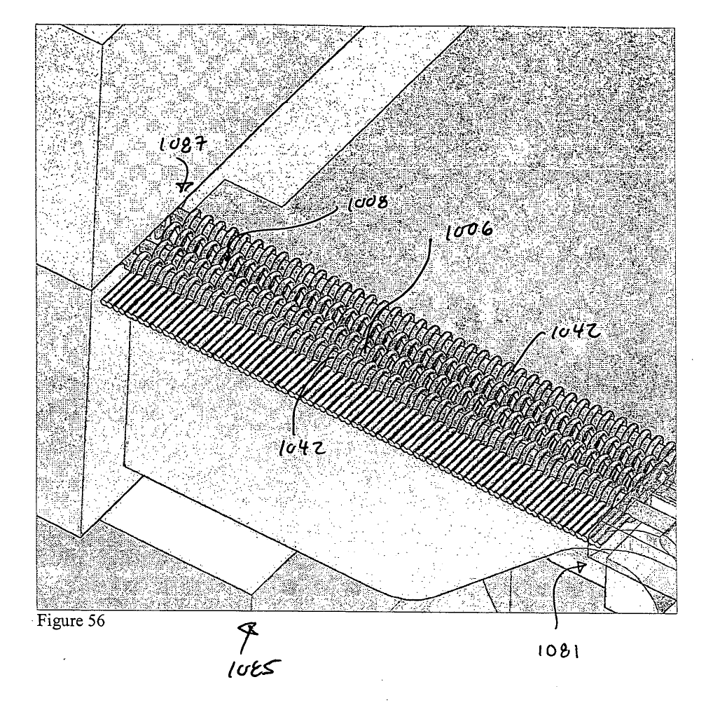

After forming, the storage magazine is moved from the forming fixture to a trimming fixture 1070 where ends 1021 of the strands 1004 are trimmed. The storage magazine 1080 is placed onto the trimming fixture, as shown in FIG. 54, which receives the storage magazine and holds it in position by aligning the base 1082 with a corresponding slot 1074 on the trimming fixture. The base of the storage magazine may be moved to different positions within the slot to accommodate different desired trim lengths of the strands 1004. Once positioned with the excess length 1021 of the formed strands lying over a first cutting edge 1076, a second, corresponding cutting edge 1078 descends and presses the strands 1004 against the first cutting edge to shear the excess length. This removes all portions of the formed strands that extend beyond the first cutting edge 1076, as shown in FIG. 55. The strands are then ready to be transferred to the next work station on the storage magazine 1080.

Trimming all of the formed strands together, after they have been formed, helps insure that all of the formed strands have a consistent length. However, in some embodiments, the formed strands are trimmed individually immediately after the forming process while still on the forming fixture, or after subsequent processes, such as after loading strands of the second set have been inserted into the passageways. Still, in other embodiments, strands of the first set are provided cut to their final length such that no trimming is necessary. Some trimming methods, like those used with strands that are not self terminating, involve trimming both ends of the formed strands on the forming fixture, or elsewhere.

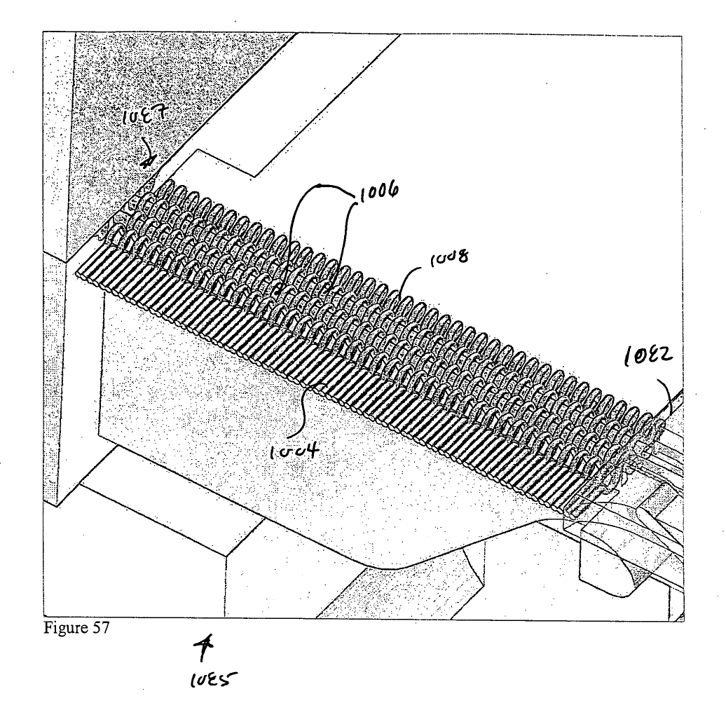

After the formed strands 1004 have been trimmed to length, they are moved, while on the storage magazine, to an insertion fixture 1085 where loading strands 1006 are inserted into the passageways 1008. As with the trimming fixture, the insertion fixture has registration features 1086 that mate with corresponding features of the storage magazine to insure accurate placement. In the illustrated embodiment, these registration features include apertures 1087 that accept the distal end 1064 of each pin 1042 and an edge 1081 that abuts the base 1082 of the storage magazine 1080, as shown in FIG. 56. The insertion fixture shown in FIGS. 56-59 also has a clamping surface 1088 (a portion of which is not shown in FIGS. 56 and 57 to provide a full view of the loading strands being inserted into the passageway) that holds the formed strands 1004 against the insertion fixture 1085 during the insertion process.

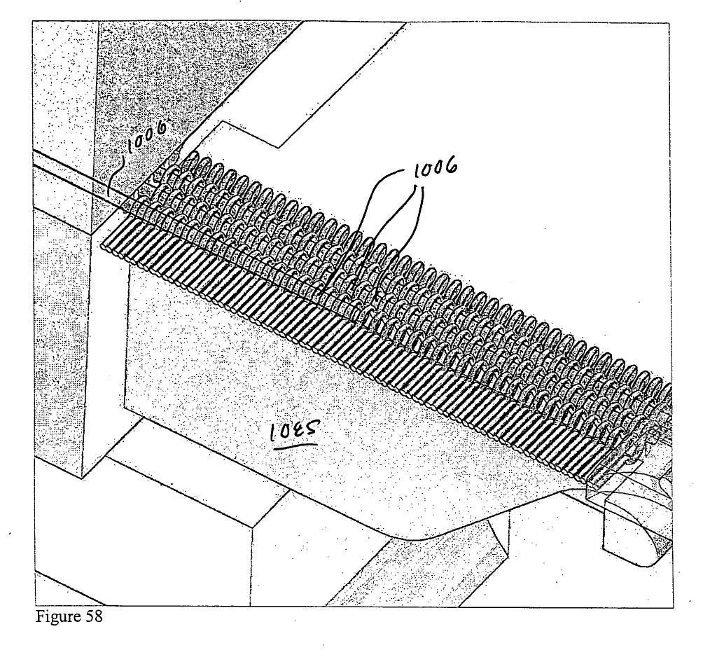

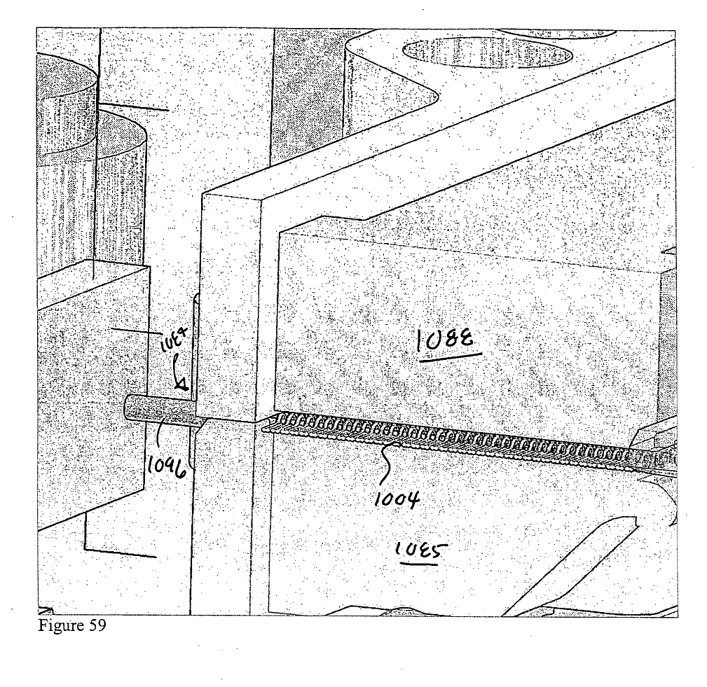

Loading strands 1006 are inserted into the passageways 1008 after the storage magazine is loaded onto the insertion fixture. First, the loading strands are fed through the passageways 1008 that are not occupied by the pins 1042 of the storage magazine 1080. In FIG. 56, these passageways are the second and third passageways. Once strands have been inserted into each of these, the storage magazine 1080 and its pins 1042 are removed from the insertion fixture, leaving the fixture and strands as shown in FIG. 57. In this state, access is provided to the remaining first and fourth passageways 1010, 1016. The remaining loading strands 1006 are then inserted into the first and fourth passageways, as shown in FIGS. 58 and 59 to complete the weave. The order of inserting the loading strands is exemplary, and the loading strands may be inserted in another suitable order.

Other embodiments of insertion fixtures may support the formed strands in different ways than the fixture illustrated in FIGS. 56-59. Some embodiments may have a corrugated surface facing the formed strands, where the corrugations coincide with the passageway peaks and valleys to provide a greater contact area. Still, other embodiments may hold the formed strands by gripping their termination ends. In other embodiments, the insertion fixture may not directly hold the strands at all, but rather, the storage magazine may support the strands without pins occupying the passageways. For instance, the storage magazine may have pins or other features that sandwich the formed strands, much like the upper and lower surface of the insertion fixture. In any of these embodiments, the surfaces that clamp the loading strands may be lined with a material, such as an elastic material, to help cushion the strands while being clamped.

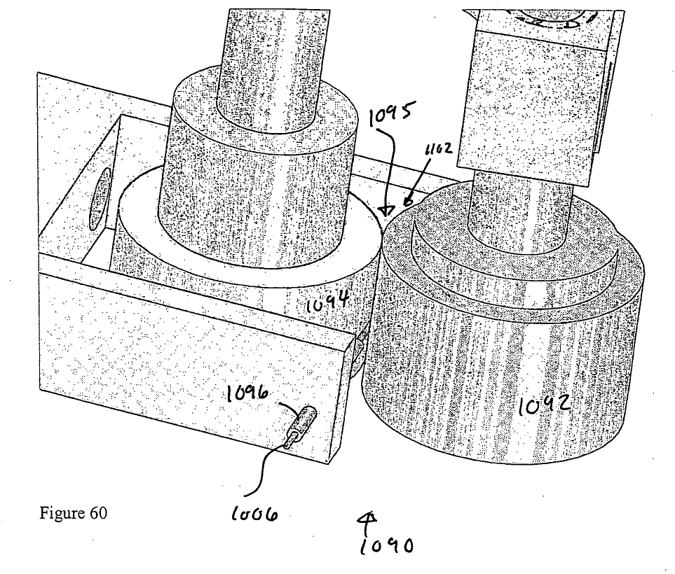

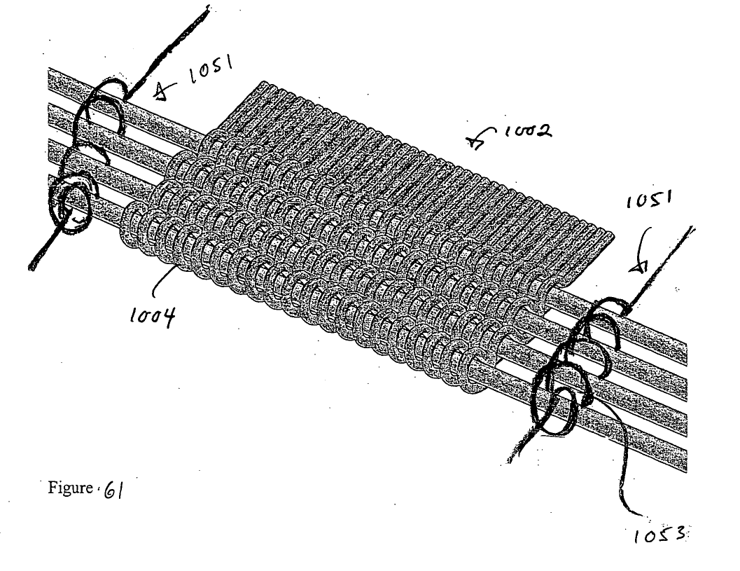

Loading strands are preferably fed through the passageways by being extended there through, rather than being pulled there through, although the invention is not limited in this respect. A driving mechanism 1090 shown in FIG. 60 is used to extend loading strands 1006 into the passageways 1008 during the insertion process. The driving mechanism has two, opposed wheels 1092, 1094 with outer surfaces that meet one another at a driving interface 1095. The opposed wheels include a drive wheel 1092 that is powered through its shaft, which, in turn drives an idler wheel 1094 by virtue of contact at the interface surface 1095. The drive mechanism is fed by a spool of continuous loading strand material (not shown) that may hold bulk strand material. A guide 1096 tube is disposed between the drive mechanism 1090 and the insertion fixture 1085 and directs the strands 1006 toward the passageway 1008 which it is to be inserted into. A cutting blade is located between the guide tube 1096 and the insertion fixture 1085 to trim each strand 1006 once it has been inserted into a given passageway.

The driving mechanism operates by feeding and guiding strand material toward passageways 1008 of the formed strands. The opposed wheels accept a strand fed from an upstream edge 1102 of the interface and propel it forward into the lumen 1098 of the guide. In one embodiment, the driving wheel is made of a hard rubber and the idler wheel comprises a steel cam follower. However, in other embodiments the driving mechanism or the wheels may be constructed in other ways, as the invention is not limited to these constructions.

The guide 1096 directs the strand through a first aperture 1087 of the insertion fixture that is aligned with the first passageway 1010 and in some embodiments the guide may be abutted directly against the insertion fixture to provide a continuous conduit into one of the passageways, although the invention is not limited to such an arrangement. The guide prevents the loading strand from deflecting too far as it is extended away from the drive wheels in a cantilevered manner. It also helps the continuous strand maintain a constant track as it is passed through the interface of the opposed wheels. Although the guide is used in some embodiments, for example when using a stiffer loading strand the guide may not be needed. The diametric clearance between the guide tube, in one embodiment, is 0.004 inches (e.g., an 0.008 inch strand within a tube with a 0.012 inch inner diameter). For smaller diameter strands, the clearance may decrease proportionally in some embodiments. For example, one embodiment used with a strand with a 0.004 inch diameter may have a guide tube with a 0.002 diametric clearance. In one illustrative embodiment, the clearance may be sized small enough to prevent the strand from buckling and large enough to prevent foreign debris, or variation in the cross sectional size of the loading strands from causing the strand to jam.

Once the strand is fully inserted into a passageway, the guide is retracted from the insertion fixture and the cutting blade is lowered to trim the loading strand length, which in some embodiments may be its finished length. The driving mechanism 1090 then indexes relative to the insertion fixture until the guide is aligned with the next passageway to receive a loading strand. The process of inserting the loading strand is then repeated until all of the passageways are filled.

In some embodiments, the loading strands may be aided during the insertion process by means other than the driving mechanism. For instance, air jets may be positioned to help keep the strands straight as they are moving towards or are passing through the passageways. Still, in other embodiments, the insertion fixture and driving mechanism may be oriented so the loading strands are fed downwardly, thereby reducing deflection of the strands that is otherwise caused by cantilevering. In yet other embodiments, a vacuum force may draw or pull the strands through the passageway from the end of the passageway opposite the drive mechanism. A temporary guide may also be placed on the distal end of the loading strand to help guide it towards or through a passageway, as the invention is not limited in this respect.

A grip, as shown in FIG. 61 may be located at each end of the insertion fixture to hold the loading strands 1006 after they are inserted into passageway 1008. The grip 1051 at either end of the fixture is a coil spring that has a compressed, natural state. The grip is opened by expanding the spring such that a gap 1053, large enough to accept a loading strand, exists between each of the coils. Before the weave is moved from the loading fixture to a subsequent work station, the end of each loading strand 1006 is placed between individual coils of the spring when it is in an expanded state. To grip the strand, the spring is allowed to return to its natural, compressed state to compress the end of each loading strand between the coils. Once the ends of each loading strand are held by the grips, the clamping surface 1088 of the insertion fixture is opened and the weave is lifted therefrom. The weave can then be transferred to a subsequent workstation for further processing.

The weave is now transferred to a subsequent work station where the formed conductive strands are terminated to a ferrule 922, made of a conductive material. In one embodiment, a cylindrical connector is to be formed like that shown in FIGS. 38-40. In one method of forming this embodiment, the terminated ends 1021 of the formed strands are placed about the outside of a ferrule, spacing each of the conductive strands equally about its circumference. Only the termination ends of each conductive strand are placed around the ferrule, not the formed passageways, so as to leave a cylindrically spaced lumen to receive the mating connector. The termination ends are then soldered to the ferrule, completing an electrical connection there between. Other suitable termination process may be employed, such as crimping or clamping, as the present invention is not limited in this respect. The weave, soldered to the ferrule and having the grip retaining the strands within the passageways, is then moved to a subsequent workstation for further processing.

After the formed strand are terminated to the conductive ferrule, the weave is transferred to a work station where the loading strands 1006 are terminated. For the illustrated connector, ends of the substantially inelastic, loading strands 1006 are wrapped about a spring member 824, like that shown in FIG. 39a. The strands are terminated by first releasing each end from the grip, and then wrapping the end about an end portion of the of the spring. A drop of fast drying adhesive is applied to the end of each strand to hold it to the spring. Other suitable arrangements for holding the loading strands to the spring may be employed as the present invention is not limited in this respect. For example, in one illustrative embodiment the loading strands may be attached to the spring member by crimping the spring element about the loading strand, as the invention is not limited to being wrapped about the spring member or being held thereto by adhesive. The spring is held in a compressed state during the wrapping process and until the adhesive has dried adequately to insure that the force applied to the loading strand by the elastic spring will not separate the loading strand therefrom. Once this process is repeated for each end of the loading strands, the connector is moved from the work station to other stations in the manufacturing process.

With strands of the first set (conductive strands) and second set (loading strands) now forming a weave connected to a ferrule and an elastic element providing compliance to the weave, the weave can now be inserted into a connector housing. FIG. 38 shows a plastic housing that contains the weave manufactured through the above described process and also shows a mating element that will connect to the connector. The woven connector may be mounted within the plastic housing through a snap-fit joint or may also be mounted through any other means as the invention is not limited in this respect. Of course, the material forming the housing may be any suitable material as the present invention is not limited in this respect.

Once the connector is assembled, as shown in FIG. 38, it may be quality tested by measuring various physical properties of the connector, such as electrical resistivity across the entire connector or various portions thereof, physical dimensions, in particular mate of mating features, or any other features that are deemed important for a particular application.

Having thus described various illustrative embodiments and aspects thereof, modifications and alterations may be apparent to those of skill in the art. Such modifications and alterations are intended to be included in this disclosure, which is for the purpose of illustration only, and is not intended to be limiting. The scope of the invention should be determined from proper construction of the appended claims, and their equivalents.

What is claimed is:

1. A method of forming a woven electrical connector, the method comprising:
providing a first set of strands and a second set of strands;
plastically deforming strands of the first set to define passageways; and then
inserting strands of the second set through the passageways to form the woven electrical connector.

2. The method of claim 1, wherein plastically deforming strands of the first set comprises plastically deforming strands of the first set about pins of a forming fixture to define at least some of the passageways.

3. The method of claim 2, wherein plastically deforming strands of the first set comprises:
wrapping strands of the first set about a first pin of the forming fixture to define a first one of the passageways; and
wrapping strands of the first set about a second pin of the forming fixture to define a second one of the passageways.

4. The method of claim 3, wherein wrapping strands of the first set comprises wrapping multiple strands of the first set about the first pin concurrently.

5. The method of claim 3, wherein plastically deforming strands of the first set further comprises:
twisting each strand of the first set after being wrapped about each of the first pin and the second pin.

6. The method of claim 1, wherein plastically deforming strands of the first set comprises:
forming corrugations in the strands of the first set with a roll forming die; and then
folding the strands of the first set to align the corrugations to form the passageways.

7. The method of claim 3, further comprising:
placing strands of the first set onto a storage magazine.

8. The method of claim 7, wherein placing strands of the first set comprises:
removing at least one of the first pin or the second pin from the respective first or second passageways of the first set of strands; and
replacing the at least one of the first pin or the second pin with a pin of the storage magazine to place the first set onto the magazine

9. The method of claim 7, wherein strands of the first set further comprises:
removing at least one of the first pin or the second pin from the respective first or second passageways of the first set of strands; and
retaining at least the other of the first pin or the second pin in the respective first or second passageway of the first set of strands as a pin of the storage magazine.

10. The method of claim 9, further comprising:
placing the storage magazine into a fixture to hold the first set of strands for subsequent insertion of strands of the second set into the passageways.

11. The method of claim 1, wherein inserting strands of the second set comprises:
driving a first of the strands of the second set between a pair of opposed wheels; and
guiding the first of the strands of the second set into one of the passageways.

12. The method of claim 11, wherein inserting strands of the second set further comprises:
cutting the first of the strands of the second set once inserted into the one of the passageways.

13. The method of claim 1, further comprising:
trimming a first end of each strand of the first set so each of the first ends are substantially aligned with one another.

14. The method of claim 1, wherein providing the first set of strands comprises providing a first set of strands including electrically conductive strands.

15. The method of claim 14, wherein providing the second set of strands comprises providing a second set of strands including electrically non-conductive material.

16. The method of claim 1, wherein providing the first set of strands comprises providing a first set of strands consisting of electrically conductive strands.

17. The method of claim 1, wherein providing the first set of strands comprises providing a first set of strands having both electrically conductive strands and electrically non-conductive strands.

18. The method of claim 1, wherein providing the second set of strands comprises providing a second set of strands including substantially inelastic strands.

19. The method of claim 18, wherein providing the second set of substantially inelastic strands comprises providing strands made of Kevlar®.

20. The method claim 18, further comprising:
connecting an end of each strand of the second set to a substantially elastic element.

21. The method of claim 1, further comprising:
assembling the woven, electrical connector into a plastic connector housing.

22. A method of forming a woven electrical connector, the method comprising:
providing a first set of strands and a second strand;
plastically deforming strands of the first set to define a passageway; and then
inserting the second strand through the passageway to form the woven electrical connector.

23. The method of claim 22, wherein plastically deforming strands of the first set comprises plastically deforming strands of the first set about a pin of a forming fixture to define the passageway.

24. The method of claim 22, further comprising:
placing strands of the first set onto a storage magazine.

25. The method of claim 24, further comprising:
placing the storage magazine into a fixture to hold the first set of strands for subsequent insertion of the second strand into the passageway.

26. The method of claim 22, wherein inserting the second strand comprises:
driving the second strand between a pair of opposed wheels; and
guiding the second strand into the passageway.

27. The method of claim 26, wherein inserting strands of the second set further comprises:
cutting the first of the second strand once inserted into the passageway.

28. The method of claim 22, further comprising:
trimming a first end of each strand of the first set so each of the first ends are substantially aligned with one another.

29. The method of claim 22, wherein providing the first set of strands comprises providing a first set of strands including electrically conductive strands.

30. The method of claim 29, wherein providing the second strand comprises providing a second electrically non-conductive strand.

31. The method of claim 22, wherein providing the first set of strands comprises providing a first set of strands consisting of electrically conductive strands.

32. The method of claim 22, wherein providing the first set of strands comprises providing a first set of strands having both electrically conductive strands and electrically non-conductive strands.

33. The method of claim 22, wherein providing the second strand comprises providing a second, substantially inelastic strand.

34. The method of claim 33, wherein providing the second substantially inelastic strand comprises providing a strand made of Kevlar®.

35. The method claim 16, further comprising:
connecting an end of the second strand to a substantially elastic element.

36. A method of forming a woven electrical connector, the method comprising:
providing a first strand and a second set of strands;
plastically deforming the first strand to define passageways; and then
inserting strands of the second set through the passageways to form the woven electrical connector.

37. The method of claim 36, wherein plastically deforming the first strand comprises plastically deforming the first strand about pins of a forming fixture to define at least some of the passageways.

38. The method of claim 37, wherein plastically deforming the first strand comprises:
wrapping the first strand about a first pin of the forming fixture to define a first one of the passageways; and
wrapping the first strand about a second pin of the forming fixture to define a second one of the passageways.

39. The method of claim 38, wherein plastically deforming the first strand further comprises:
twisting the first strand after being wrapped about each of the first pin and the second pin.

40. The method of claim 38, further comprising:
placing strands of the first set onto a storage magazine.

41. The method of claim 40, wherein placing strands of the first set further comprises:
removing at least one of the first pin or the second pin from the respective first or second passageways of the first strand; and
retaining at least the other of the first pin or the second pin in the respective first or second passageway of the first strand as a pin of the storage magazine.

42. The method of claim 41, further comprising:
placing the storage magazine into a fixture to hold the first strand for subsequent insertion of strands of the second set into the passageways.

43. The method of claim 36, wherein inserting strands of the second set comprises:
driving a first of the strands of the second set between a pair of opposed wheels; and
guiding the first of the strands of the second set into one of the passageways.

44. The method of claim 36 further comprising:
cutting the first of the strands of the second set once inserted into the one of the passageways.

45. The method of claim 36, wherein providing the second set of strands comprises providing a second set of strands including substantially inelastic strands.

46. The method of claim 45, wherein providing the second set of substantially inelastic strands comprises providing strands made of Kevlar®.

47. The method claim 47, further comprising:
connecting an end of each strand of the second set to a substantially elastic element.

48. A method of forming a woven, electrical connector, the method comprising:
providing a first set of strands constructed and arranged to define passageways there through;
providing a second set of strands; and
extending strands of the second set from a driving mechanism and into the passageways of the first set to form the woven, electrical connector.

49. The method of claim 20, wherein extending strands of the second set comprises extending strands from a pair of opposed wheels of the driving mechanism.

50. The method of claim 21, further comprising:
guiding the strands of the second set toward the passageways with a guide tube.

51. The method of claim 22, further comprising:
cutting each of the strands of the second set.

52. The method of claim 20, wherein extending strands of the second set comprises extending a first strand of the second set before extending a second strand of the second set.

53. The method of claim 20, wherein providing the first set of strands comprises providing a first set of strands having electrically conductive strands.

54. The method of claim 25, wherein providing the second set of strands comprises providing a second set of strands having electrically non-conductive strands.

55. The method of claim 26, wherein providing strands of the second set comprises providing a second set having substantially inelastic strands.

56. The method of claim 27, wherein providing substantially inelastic strands comprises providing strands made of Kevlar®.

57. A method of forming a woven, electrical connector, the method comprising:
providing at least a first and second formed strand, each of the first and second formed strands defining a plurality of passageways there through;
aligning the plurality of passageways of each of the first and second formed strands; and then
inserting strands of a second set through the passageways of each of the first and second strands to form the woven, electrical connector.

58. A method of forming a woven electrical connector, the method comprising:
providing a first set of strands consisting of electrically conductive strands;
providing a second set of strands consisting of substantially inelastic, non-conductive strands;
wrapping strands of the first set about a first pin of a forming fixture to define a first passageways;
wrapping strands of the first set about a second pin of the forming fixture to define a second passageways;
removing at least one of the first pin or the second pin from the respective first or second passageways of the first set of strands;
retaining at least the other of the first pin or the second pin in the respective first or second passageway of the first set of strands as a pin of a storage magazine;
placing the storage magazine into a fixture to hold the first set of strands for subsequent trimming of strands of the first set;
trimming a first end of each strand of the first set so each of the first ends are substantially aligned with one another;
placing the storage magazine into a fixture to hold the first set of strands for subsequent insertion of strands of the second set into the passageways;
driving a first of the strands of the second set between a pair of opposed wheels;
guiding the first of the strands of the second set into one of the passageways; and
cutting the first of the strands of the second set once inserted into the one of the passageways.

59. An apparatus for forming a woven, electrical connector, the apparatus comprising:
a fixture adapted to retain a first set of strands that define passageways there through;
a driving mechanism constructed and arranged to extend strands of a second set away from the driving mechanism and into passageways of the first set of strands.

60. The apparatus of claim 59, wherein the fixture includes a first and second clamping surface constructed and arranged to clamp the first set of strands.

61. The apparatus of claim 59, wherein the fixture is adapted to retain the first set of strands with at least one pin passing through one of the passageways.

62. The apparatus of claim 59, wherein the fixture includes at least one aperture aligned with one of the passageways and providing access thereto.

63. The apparatus of claim 59, wherein the driving mechanism includes opposed wheels.

64. The apparatus of claim 59, further comprising:
a guide adapted to direct strands of the second set into the passageways, the guide disposed between the fixture and the driving mechanism.

65. A storage magazine for retaining strands shaped with passageways, the storage magazine comprising:
a base;
a plurality of pins extending from the base, the pins constructed and arranged to retain a set of formed strands for assembly into an electrical connector.

66. The storage magazine of claim 65, wherein the plurality of pins include two pins.
